(19) United States
(12) Patent Application Publication
(10) Pub. No.: US 2018/0107112 A1
(43) Pub. Date: Apr. 19, 2018

(54) TRANSFER-TYPE PHOTOSENSITIVE REFRACTIVE INDEX ADJUSTMENT FILM, METHOD FOR FORMING REFRACTIVE INDEX ADJUSTMENT PATTERN, AND ELECTRONIC COMPONENT

(71) Applicant: Hitachi Chemical Company, Ltd., Tokyo (JP)

(72) Inventors: Mayumi SATO, Tokyo (JP); Tadahiro KIMURA, Tokyo (JP); Kazuhito WATANABE, Tokyo (JP); Takumi WATANABE, Tokyo (JP)

(21) Appl. No.: 15/573,150

(22) PCT Filed: May 11, 2015
(86) PCT No.: PCT/JP2015/002379

§ 371 Date: Nov. 10, 2017

(51) Int. Cl. G03F 7/033; G03F 7/004; G03F 7/20; G06F 3/044; B32B 27/08; B32B 27/20; B32B 37/26; B32B 38/10; H05K 3/28

(52) U.S. Cl. CPC G03F 7/033; G03F 7/0045; G03F 7/20; G06F 3/044; B32B 2307/418; B32B 27/20; B32B 37/26; B32B 38/10; H05K 3/287; B32B 27/08

(57) ABSTRACT

A transfer type photosensitive refractive index adjustment film that comprising: a support film, a photosensitive resin layer provided on the support film and a high-refractive index layer provided on the photosensitive resin layer, the photosensitive resin layer comprises a photopolymerizable compound and a photopolymerization initiator, and the photopolymerization initiator comprises an oxime ester compound or a phosphine oxide compound.

### TECHNICAL FIELD

The present invention relates to a transfer-type photosensitive refractive index adjustment film, a method for forming a refractive index adjustment pattern and an electronic component. In particular, the present invention relates to a transfer-type photosensitive refractive index adjustment film that can form easily a cured film having both functions; i.e. a function as a protective film of a transparent electrode, and a function of allowing a transparent electrode pattern to be invisible or improving visibility of a touch screen.

### BACKGROUND ART

In a display, etc. of a large-sized electronic device such as PCs and TVs, a small-sized electronic device such as a car navigation, a portable phone and an electronic dictionary, an OA or FA device, a liquid crystal display device or a touch panel (touch sensor) is used. In these liquid crystal display devices or touch panels, an electrode made of a transparent electrode material is provided. As the transparent electrode material, ITO (Indium-Tin-Oxide), indium oxide or tin oxide constitutes the mainstream thereof since they exhibit high transmittance for visible rays.

As the touch panel, various types of touch panel have already been put into practical use. Since it enables finger tips to conduct multiple detection, a projected capacitive touch panel has excellent operability that it can issue complicated instructions. Due to such excellent operability, in a device having a small-sized display such as a portable phone or a portable music player, a projected capacitive touch panel has been actively used as an input device on a display screen.

In general, in a projected capacitive touch panel, in order to express two-dimensional coordinates of the X-axis and the Y-axis, plural X electrodes and plural Y electrodes that cross orthogonally the X electrodes form a two-layer structure pattern. As these electrodes, in recent years, use of conductive fibers, the representative examples of which include Ag nanowires and carbon nanotubes, has been examined. However, ITO still constitutes the mainstream of the electrode material.

Meanwhile, in a perimeter area of a touch panel, in order to transmit detected signals of touch positions, metal wiring is required to be provided. In respect of conductivity, the metal wiring is generally formed of copper.

When contacting the finger tips, corrosive components such as water and salt may enter the inside of a touch panel from a sensing area. If corrosive components enter the inside of a touch panel, the above-mentioned metal wiring corrodes, and as a result, an electrical resistance between an electrode and a driving circuit may be increased or disconnection may occur.

In order to prevent corrosion of metal wiring, the inventors of the present invention proposed a method in which a photosensitive resin layer formed of a specific photosensitive resin composition is provided on a transparent substrate, and the metal wiring is protected by exposing this photosensitive resin layer to light, followed by development (see Patent Document 1, for example).

As mentioned above, in a projected capacitive touch panel, on a substrate, plural X electrodes and plural Y electrodes that cross orthogonally to the X electrodes made of transparent electrode materials are formed, thereby to form a transparent electrode pattern having a two-layer structure. A difference in color becomes large due to optical reflection of a part in which a transparent electrode pattern is formed and a part in which a transparent electrode pattern is not formed. As a result, when it is formed into a module, the so-called “pattern visibility phenomenon” in which a transparent electrode pattern is pictured in a screen may occur. Further, between a substrate and a transparent electrode or between a visibility improvement film (OCA: Optical Clear Adhesive) that adheres a cover glass used for forming the film into a module and a transparent electrode pattern, the intensity of reflected light is increased to lower the transmission ratio of a screen.

The method described in Patent Document 1 was effective in protecting the metal wiring, but had room for improvement in suppressing pattern visibility phenomenon or lowering transmittance of a screen.

As a means for preventing the transparent electrode pattern from being visible, a transfer film having a first curable transparent resin layer with a low refractive index and a second curable transparent resin layer with a high refractive index is disclosed (see Patent Document 2, for example).

### RELATED ART DOCUMENT

### Patent Documents

Patent Document 1: WO2013/084873
Patent Document 2: WO2014/084112

### SUMMARY OF THE INVENTION

However, the transfer film in Patent Document 2 has insufficient transparency, and has room for further improvement. In addition, this technology has room for improvement that developability is not insufficient when forming a prescribed cured film, and that it is not capable of forming a cured film that realizes both suppression of lowering in transmittance of a screen and protection of the metal wiring of a sensor. As the specific transfer configuration, a six-layered film formed of a temporary support/thermoplastic resin layer/intermediate layer/first curable transparent resin layer/second curable transparent resin layer/protective film is disclosed. This film has room for improvement in respect of productivity of a multi-layer film.

An object of the present invention is to provide a transfer-type photosensitive refractive index adjustment film that is capable of forming easily with sufficient developability a cured film that can attain both prevention of “pattern visibility phenomenon” of a transparent electrode, lowering in transmittance of a screen and protection of a sensor metal wiring, and has sufficient transparency.

The inventors of the present invention made intensive studies in order to solve the above-mentioned problem. As a result, the inventors have found that, a thin IM layer can be formed on a transparent conductive pattern by using a transfer-type photosensitive refractive index adjustment film composed of a photosensitive resin layer containing a specific photopolymerization initiator and a high-refractive index layer, suppression of an increase in difference in color, suppression of the “pattern visibility phenomenon” and improvement of visibility of a touch screen by elimination of lowering in transmittance of a screen and prevention of corrosion of the metal wiring can be attained simultaneously. The present invention has been made based on these findings.

Specific embodiments of the present invention are shown below.
1. A transfer-type photosensitive refractive index adjustment film comprising:

a support film, a photosensitive resin layer provided on the support film and a high-refractive index layer provided on the photosensitive resin layer,

the photosensitive resin layer comprises a photopolymerizable compound and a photopolymerization initiator, and

the photopolymerization initiator comprises an oxime ester compound or a phosphine oxide compound.
2. The transfer-type photosensitive refractive index adjustment film according to 1, wherein the minimum value of the visible ray transmittance at a wavelength of 400 to 700 nm of the photosensitive resin layer and the high-refractive index layer is 90.00% or more.
3. The transfer-type photosensitive refractive index adjustment film according to 1 or 2, wherein the high-refractive index layer comprises a compound having a triazine ring or a compound having an isocyanuric acid.
4. The transfer-type photosensitive refractive index adjustment film according to any one of 1 to 3, wherein the high-refractive index layer comprises a compound having a fluorene skeleton.
5. The transfer-type photosensitive refractive index adjustment film according to any one of 1 to 4, wherein the high-refractive index layer comprises a metal oxide.
6. The transfer-type photosensitive refractive index adjustment film according to 5, wherein the metal oxide is at least one selected from the group consisting of zirconium oxide, titanium oxide, tin oxide, zinc oxide, indium tin oxide, indium oxide, aluminum oxide, silicon oxide and yttrium oxide.
7. The transfer-type photosensitive refractive index adjustment film according to any one of 1 to 6, wherein the refractive index at a wavelength of 633 nm of the high-refractive index layer is 1.50 to 1.90.
8. The transfer-type photosensitive refractive index adjustment film according to any one of 1 to 7, wherein the thickness of the high-refractive index layer is 10 to 500 nm.
9. The transfer-type photosensitive refractive index adjustment film according to any one of 1 to 8, wherein the photosensitive resin layer comprises a binder polymer.
10. The transfer-type photosensitive refractive index adjustment film according to 9, wherein the binder polymer has a carboxyl group.
11. The transfer-type photosensitive refractive index adjustment film according to 9 or 10, wherein the binder polymer comprises a structural unit derived from at least one compound selected from the group consisting of (meth)acrylic acid, (meth)acrylic acid glycidyl ester, (meth)acrylic acid benzyl ester, styrene, (meth)acrylic acid methyl ester, (meth)acrylic acid ethyl ester, meth(acrylic) butyl ester and (meth)acrylic acid 2-ethylhexyl ester.
12. The transfer-type photosensitive refractive index adjustment film according to any one of 1 to 11, wherein the photosensitive resin layer comprises a phosphoric acid ester compound.
13. The transfer-type photosensitive refractive index adjustment film according to any one of 1 to 12, wherein the total thickness of the photosensitive resin layer and the high-refractive index layer is 30 μm or less.
14. A method for forming a refractive index adjustment pattern that comprises:

a step of laminating the high-refractive index layer and the photosensitive resin layer by using the transfer-type photosensitive refractive index adjustment film according to any one of 1 to 13 such that the high-refractive index layer is in close contact with a substrate; and

a step of forming a refractive index adjustment pattern in which, after exposing prescribed parts of the high-refractive index layer and the photosensitive resin layer on the substrate, parts other than said prescribed parts are removed, thereby to form a refractive index adjustment pattern.
15. An electronic component having a refractive index adjustment pattern obtained by the forming method according to 14.

According to the present invention, it is possible to provide a transfer-type photosensitive refractive index adjustment film capable of forming a cured film easily with sufficient developability that has both a function of lowering of suppression of pattern invisibility phenomenon and protecting sensor metal wiring, and has sufficient transparency.

### BRIEF DESCRIPTION OF THE DRAWINGS

FIG. 1 is a schematic cross-sectional view showing the transfer-type photosensitive resin refractive index adjustment film of the present invention;

FIG. 2 is a schematic cross-sectional view showing one embodiment in which the transfer-type photosensitive resin refractive index adjustment film of the present invention is used in a substrate provided with a transparent conductive pattern; and

FIG. 3 is a schematic plan view showing the electronic component according to one embodiment of the present invention.

### MODE FOR CARRYING OUT THE INVENTION

Hereinbelow, the mode for carrying out the present invention will be explained in detail. However, the present invention is not limited to the embodiments mentioned below.

In the specification, the “(meth)acrylic acid” means an acrylic acid or a methacrylic acid, and the “(meth)acrylate” means acrylate or methacrylate corresponding thereto. The “A or B” means inclusion of either one of A and B or inclusion of both A and B.

In the specification, the “step” includes not only an independent step. That is, if a step cannot be clearly distinguished from other steps, the step is included in the “step” as long as the step attains its prescribed effects. The numerical range indicated by using “to” means a range including numerical values indicated before and after the “to” as a minimum value and a maximum value, respectively.

Further, as for the content of each component in the composition in the specification, when plural substances corresponding to these components are present in the composition, unless otherwise indicated, the content means the total amount of these plural substances in the composition. In addition, unless otherwise indicated, exemplified materials may be used singly or in combination of two or more.

### (Transfer-Type Photosensitive Refractive Index Adjustment Film)

The transfer-type photosensitive refractive index adjustment film of the present invention comprises a supporting film, a photosensitive resin layer provided on the supporting film and a high-refractive index layer provided on the photosensitive resin layer, and is characterized in that the photosensitive resin layer contains a photopolymerizable compound and a photopolymerization initiator, and the photopolymerization initiator contains an oxime ester compound or a phosphine oxide compound.

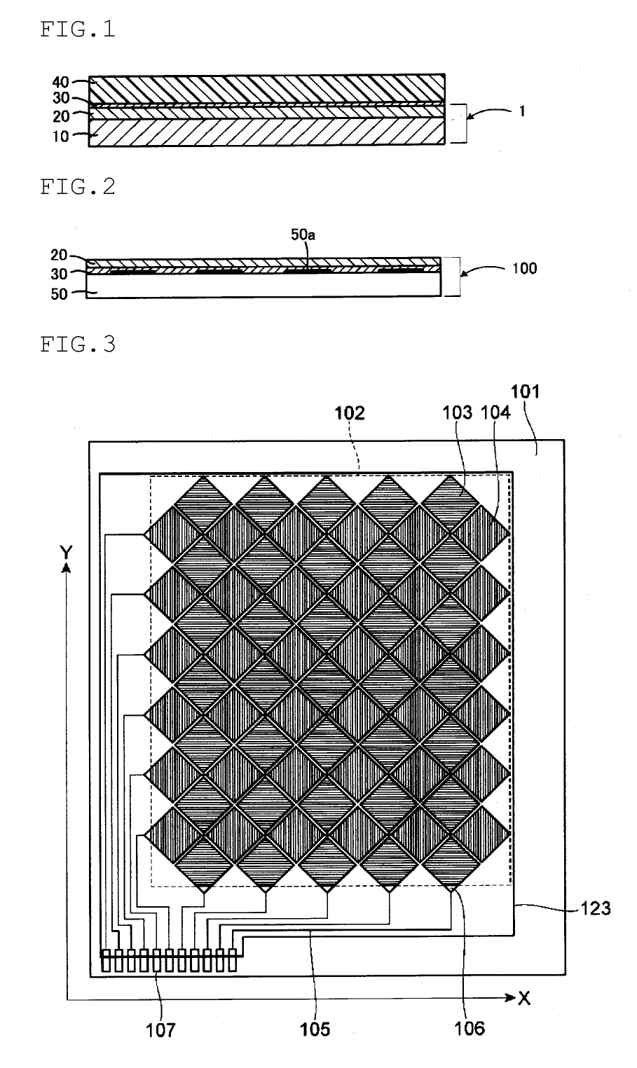

FIG. 1 is a schematic cross sectional view showing one embodiment of the transfer-type photosensitive refractive index adjustment film according to the present invention. A transfer-type photosensitive refractive index film 1 shown in FIG. 1 is provided with a supporting film 10, a photosensitive resin layer 20 provided on the supporting film, and a high-refractive index layer 30 provided on the photosensitive resin layer. As shown in FIG. 1, the transfer-type photosensitive refractive index adjustment film may comprise a protective film 40 provided on the side opposite to the photosensitive resin layer 20 of the high-refractive index layer 30.

In the specification of the present invention, the boundary between the high-refractive index layer and the photosensitive resin layer is not necessarily clear, and it may be in a state in which the photosensitive resin layer is mixed with the high-refractive index layer.

By using the above-mentioned transfer-type photosensitive refractive index adjustment film, a cured film that satisfies, for example, a function of protecting the metal wiring in the perimeter of a touch panel or a transparent electrode and a function of allowing a transparent electrode pattern to be invisible or improving visibility of a touch screen can be formed simultaneously.

FIG. 2 is a schematic cross-sectional view showing one embodiment in which the transfer-type photosensitive refractive-index adjustment film of the present invention is used in a substrate provided with a transparent electrode pattern. In FIG. 2, a high-refractive index layer 30 is provided on a substrate 50 with a transparent electrode pattern 50a such as ITO such that it covers the pattern 50a. A photosensitive resin layer 20 is provided thereon, whereby a laminate 100 is configured.

Hereinbelow, an explanation is made on the supporting film, the photosensitive resin layer, the high-refractive index layer and the protective film.

### (Supporting Film)

As the supporting film 10, a polymer film can be used. As the polymer film, polyethylene terephthalate, polycarbonate, polyethylene, polypropylene, polyethersulfone, cycloolefin polymer or the like can be given. Among these, polyethylene terephthalate or cycloolefin polymer is preferable.

As for the thickness of the supporting film 10, in respect of lamination property of the photosensitive resin layer and in respect of suppressing lowering in resolution when irradiating active rays through the supporting film 10, the thickness is preferably 5 to 100 μm, more preferably 10 to 70 μm, further preferably 15 to 40 μm, and particularly preferably 15 to 35 μm.

### (Photosensitive Resin Layer)

In the present invention, the photosensitive resin layer 20 comprises a photopolymerizable compound and a photopolymerization initiator, and the photopolymerization initiator comprises an oxime ester compound or a phosphine oxide compound. In the present invention, by using an oxime ester compound or a phosphine oxide compound as the photopolymerization initiator, it is possible to form a cured film having high transparency with sufficient developability.

It is preferred that, in the photopolymerizable compound used in the present invention, it is preferable to use a compound having an ethylenically unsaturated group. As the photopolymerizable compound having an ethylenically unsaturated group, a monofunctional vinyl monomer, a bifunctional vinyl monomer, or a polyfunctional vinyl monomer having at least three polymerizable ethylenically unsaturated groups can be given.

As the monofunctional vinyl polymer, (meth)acrylic acid, (meth)acrylic acid benzyl ester, styrene, (meth)acrylic acid methyl ester, (meth)acrylic acid ethyl ester, (meth)acrylic acid butyl ester, (meth)acrylic acid 2-ethylhexyl ester, etc., can be given.

As the bifunctional vinyl monomer, polyethylene glycol di(meth)acrylate, trimethylolpropane di(meth)acrylate, polypropylene glycol di(meth)acrylate, 2,2-bis(4-(meth)acryloxypolyethoxypolypropoxyphenyl)propane, bisphenol A diglycidyl ether di(meth)acrylate; di(meth)acrylate having a dicyclopentanyl structure or a dicyclopentenyl structure or the like can be given.

As the polyfunctional vinyl monomer having at least three ethylenically polymerizable unsaturated groups, those conventionally known in the art can be used without particular restrictions. In respect of prevention of corrosion of the metal wiring or the transparent electrode and in respect of developability, it is preferable to use a (meth)acrylate compound having a skeleton derived from trimethylol propane such as trimethylol propane tri(meth)acrylate; a (meth)acrylate compound having a skeleton derived from tetramethylol methane such as tetramethylol methane tri(meth)acrylate and tetramethylol methane tetra(meth)acrylate; a (meth)acrylate compound having a skeleton derived from pentaerythritol such as pentaerythritol tri(meth)acrylate and pentaerythritol tetra(meth)acrylate; a meth(acrylate) compound having a skeleton derived from dipentaerythritol such as dipentaerythritol penta(meth)acrylate and dipentaerythritol hexa(meth)acrylate; a (meth)acrylate compound having a skeleton derived from ditrimethylol propane such as ditrimethylol propane tetra(meth)acrylate; or a (meth)acrylate compound having a skeleton derived from diglycerin.

More specifically, it is preferable to include a (meth)acrylate compound having a skeleton derived from pentaerythritol, a (meth)acrylate compound having a skeleton derived from dipentaerythritol, a (meth)acrylate compound having a skeleton derived from trimethylolpropane or a (meth)acrylate compound having a skeleton derived from ditrimethylolpropane. It is more preferable to include a (meth)acrylate compound having a skeleton derived from dipentaerythritol or a (meth)acrylate compound having a skeleton derived from ditrimethylolpropane. It is further preferable to include a (meth)acrylate compound having a skeleton derived from ditrimethylolpropane.

As for the “(meth)acrylate compound having a skeleton derived from . . . ”, an explanation will be made taking as an example a (meth)acrylate compound having a skeleton derived from ditrimethylolpropane. The (meth)acrylate having a skeleton derived from ditrimethylolpropane means an esterified product of ditrimethylolpropane and (meth)acrylic acid. The esterified product includes compounds obtained by esterifying an alkylene oxy group. It is preferred that the maximum number of ester bonds in a single molecule of the esterified product mentioned above be 4. Compounds having 1 to 3 ester bonds may be mixed in.

It is preferred that the photopolymerizable polymer contain at least three polymerizable ethylenically unsaturated groups in a single molecule. Taking into consideration a case where a monofunctional vinyl monomer or a bifunctional vinyl monomer is used in combination, in respect of improving photocurability and prevention of electrode corrosion, the amount ratio of a monomer having at least three polymerizable ethylenically unsaturated groups in a molecule is preferably 30 to 100 parts by mass, more preferably 50 to 100 parts by mass and further preferably 75 to 100 parts by mass, relative to 100 parts by mass of the total amount of the photopolymerizable compounds contained in the photosensitive resin composition.

The oxim ester compound as the photopolymerization initiator is preferably a compound represented by the following formula (1), a compound represented by the following formula (2) or a compound represented by the following formula (3):

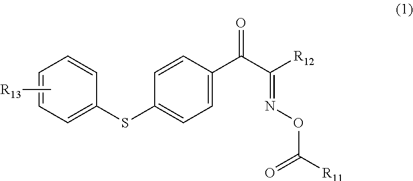

In the formula (1), R₁₁ and R₁₂ are independently an alkyl group having 1 to 12 carbon atoms, a cycloalkyl group having 4 to 10 carbon atoms, a phenyl group or a tolyl group. Among these, R₁₁ and R₁₂ are preferably an alkyl group having 1 to 8 carbon atoms, a cycloalkyl group having 4 to 6 carbon atoms, a phenyl group or a tolyl group, more preferably an alkyl group having 1 to 4 carbon atoms, a cycloalkyl group having 4 to 6 carbon atoms, a phenyl group or a tolyl group, with a methyl group, a cyclopentyl group, a phenyl group or a tolyl group being further preferable.

R₁₃ is —H, —OH, —COON, —O(CH₂)OH, —O(CH₂)₂OH, —COO(CH₂)OH or —COO(CH₂)₂OH. R₁₃ is preferably —H, —O(CH₂)OH, —O(CH₂)₂OH, —COO(CH₂)OH or —COO(CH₂)₂OH, more preferably —H, —O(CH₂)₂OH or —COO(CH₂)₂OH.

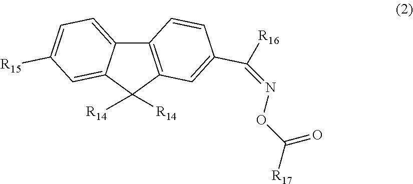

In the formula (2), plural R₁₄s are independently an alkyl group having 1 to 6 carbon atoms, and are preferably a propyl group. The plural R₁₄s may be the same or different. R₁₅ is NO₂ or ArCO (wherein Ar is a phenyl group or a tolyl group). As the Ar, a tolyl group is preferable.

R₁₆ and R₁₇ are independently an alkyl group having 1 to 12 carbon atoms, a phenyl group or a tolyl group. A methyl group, a phenyl group or a tolyl group are preferable.

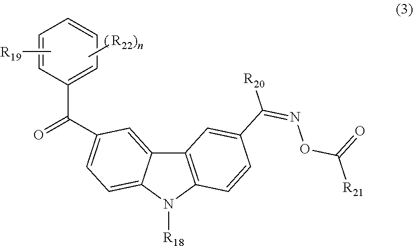

In the formula (3), R₁₈ is an alkyl group having 1 to 6 carbon atoms, with an ethyl group being preferable.

R₁₉ is an organic group having an acetal bond, and is preferably a substituent that corresponds to R₁₉ contained in a compound represented by the formula (3-1) given later.

R₂₀ and R₂₁ are independently an alkyl group having 1 to 12 carbon atoms, a phenyl group or a tolyl group. R₂₀ and R₂₁ are preferably a methyl group, a phenyl group or a tolyl group, with a methyl group being more preferable.

R₂₂ is an alkyl group having 1 to 6 carbon atoms. n is an integer of 0 to 4. When plural R₂₂s are present, the plural R₂₂s may be the same or different.

As the compound represented by the formula (1), a compound represented by the following formula (1-1) and a compound represented by the following formula (1-2) can be given. The compound represented by the following formula (1-1) can be commercially available as IRGACURE OXE 01 (manufactured by BASF Japan, Ltd.).

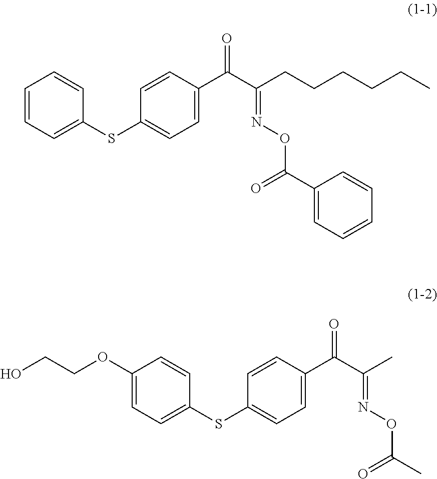 [SMILES: CCCCCC/C(=N\OC(=O)c1ccccc1)C(=O)c1ccc(Sc2ccccc2)cc1 ; CC(=O)O/N=C(\C)C(=O)c1ccc(Sc2ccc(OCCO)cc2)cc1]

As the compound represented by the above formula (2), a compound represented by the following formula (2-1) can be given. The compound represented by the following formula (2-1) can be commercially available as DFI-091 (manufactured by Daito Chemix Co., Ltd.).

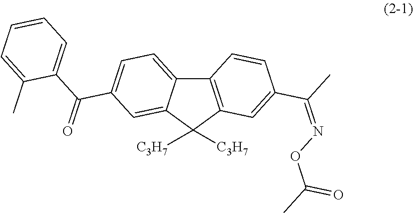

As the compound represented by the above formula (3), a compound represented by the following formula (3-1) can be given. The compound represented by the following formula (3-1) can be commercially available as Adeka Optomer-N-1919 (product name, manufactured by Adeka Corporation).

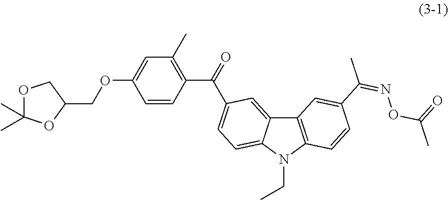 [SMILES: CCn1c2ccc(C(=O)c3ccc(OCC4COC(C)(C)O4)cc3C)cc2c2cc(/C(C)=N\OC(C)=O)ccc21]

As other oxime ester compounds, it is preferable to use a compound represented by the following formula (4) or a compound represented by the following formula (5):

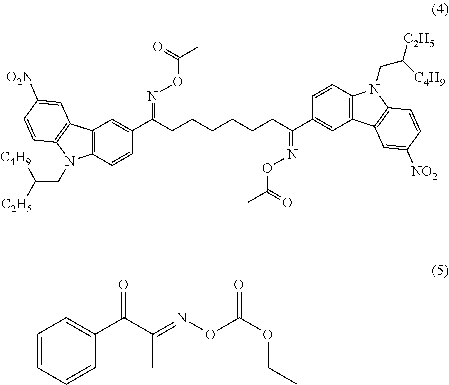

As the phosphine oxide compound, a compound represented by the following formula (6) or a compound represented by the following formula (7) can be given. In respect of quick curability and transparency, a compound represented by the following formula (6) is preferable.

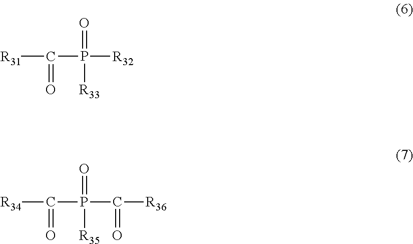

In the formula (6), R₃₁, R₃₂ and R₃₃ are independently an alkyl group having 1 to 20 carbon atoms, a phenyl group, a tolyl group, a xylyl group or a mesityl group.

In the formula (7), R₃₄, R₃₅ and R₃₆ are independently an alkyl group having 1 to 20 carbon atoms, a phenyl group, a tolyl group, a xylyl group, a mesityl group or a dimethoxyphenyl group.

The alkyl group having 1 to 20 carbon atoms may be any of a linear, branched or cyclic alkyl group. The number of carbon atoms of the alkyl group is preferably 1 to 10, further preferably 1 to 4, with a methyl group being significantly preferable.

Among the compounds represented by the formula (6), compounds in which R₃₁, R₃₂ and R₃₃ are a phenyl group, a tolyl group, a xylyl group or a mesityl group is preferable.

Among the compounds represented by the formula (7), compounds in which R₃₄, R₃₅ and R₃₆ are a phenyl group, a tolyl group, a xylyl group, a mesityl group or a dimethoxyphenyl group is preferable.

As the compound represented by the formula (6), in respect of transparency of the formed protective film and pattern forming property when the film thickness is 10 μm or less, 2,4,6-trimethylbenzoyl-diphenyl-phosphine oxide is preferable. This compound is commercially available as LUCIRIN TPO (product name, manufactured by BASF Japan, Ltd.), for example.

The photosensitive resin layer may contain a photopolymerization initiator other than the above-described oxime ester compound and phosphine oxide compound. As the photopolymerization initiator other than the oxime ester compound and the phosphine oxide compound include aromatic ketones such as benzophenonone, 4-methoxy-4′-dimethylaminobenzophenone and 2-benzyl-2-dimethylamino-1-(4-morpholinophenyl)-butanone-1,2-methyl-1-[4-(methylthio)phenyl]-2-morpholino-propanone-1; benzoin ether compounds such as benzoin methyl ether, benzoin ethyl ether and benzoin phenyl ether; benzoin compounds such as benzoin, methyl benzoin and ethyl benzoin; benzyl derivatives such as benzyl dimethyl ketal; acridine derivative such as 9-phenylacridine and 1,7-bis(9,9′-acridinyl)heptane; N-phenylglycine and N-phenylglycine derivative; cumarine-based compound; oxazole-based compound or the like can be given. A combination of a thioxanthone compound and a tertiary amine compound may be used like a combination of diethylthioxanthone and dimethylaminobenzoic acid.

It is preferred that the photosensitive resin layer contain a binder polymer in addition to the photopolymerizable compound and the photopolymerization initiator.

As the binder polymer, in respect of enabling patterning by alkali development, it is preferable to use a polymer having a carboxyl group.

As the binder polymer, a copolymer comprising structural units derived from (meth)acrylic acid and (meth)acrylic acid alkyl ester is preferable. The copolymer mentioned above may contain, as its structural unit, other monomers that can copolymerize with the (meth)acrylic acid and the (meth)acrylic acid alkyl ester. Specifically, (meth)acrylic acid glycidyl ester, (meth)acrylic acid benzyl ester, styrene or the like can be given.

As the above-mentioned (meth)acrylic acid alkyl ester, (meth)acrylic acid methyl ester, (meth)acrylic acid ethyl ester, (meth)acrylic acid butyl ester, (meth)acrylic acid 2-ethylhexyl ester, (meth)acrylic acid hydroxyl ethyl ester or the like can be given.

Among these, in respect of alkaline developability (in particular, for an inorganic aqueous alkaline solution), patterning property and transparency, a binder polymer containing a structural unit derived from at least one compound selected from (meth)acrylic acid, (meth)acrylic acid glycidyl ester, (meth)acrylic acid benzyl ester, styrene, (meth)acrylic acid methyl ester, (meth)acrylic acid ethyl ester, (meth)acrylic acid butyl ester and (meth)acrylic acid 2-ethylhexyl ester is preferable.

In respect of resolution, the weight-average molecular weight of the component (A) is preferably 10,000 to 200,000, more preferably 15,000 to 150,000, further preferably 30,000 to 150,000, particularly preferably 30,000 to 100,000, with 40,000 to 100,000 being significantly preferable. Meanwhile, the weight-average molecular weight can be measured by a gel permeation method with reference to the Examples of the present specification.

The acid value of the binder polymer is preferably 75 mgKOH/g or more in respect of alkaline developability. Further, in respect of attaining both easiness in control of the shape of a protective film and rust prevention of a protective film, the acid value is preferably 75 to 200 mgKOH/g, more preferably 75 to 150 mgKOH/g, further preferably 75 to 120 mgKOH/g, with 78 mg to 120 mgKOH/g being particularly preferable. The acid value can be measured with reference to the Examples of the present specification.

In respect of further improving rust prevention properties, the hydroxyl value of the binder polymer is preferably 50 mgKOH/g or less, more preferably 45 mgKOH/g or less. The hydroxyl value can be measured with reference to the Examples of the present specification.

In the photosensitive resin layer, as for the contents of the binder (hereinafter often referred to as component (A)) and the photopolymerizable compound (hereinafter often referred to as the component (B)), the content of the component (A) is preferably 0 to 85 parts by mass, more preferably 15 to 80 parts by mass, further preferably 20 to 80 parts by mass, particularly preferably 50 to 70 parts by mass and significantly preferably 55 to 65 parts by mass, relative to 100 parts by mass of the total amount of the component (A) and the component (B). In particular, in respect of maintaining pattern-forming property or transparency of a protective film, the content of the component (A) is preferably 15 parts by mass or more, more preferably 40 parts by mass or more, further preferably 50 parts by mass or more, and particularly preferably 55 parts by mass or more relative to 100 parts by mass of the total amount of the component (A) and the component (B).

As for the content of the photopolymerization initiator (hereinbelow often referred to as the component (C)), in respect of excellent photosensitivity and resolution, the content is preferably 0.1 parts by mass or more relative to 100 parts by mass of the total amount of the component (A) and the component (B), and in respect of excellent visible ray transmittance, the content is preferably 20 parts by mass or less.

When an oxime ester compound is contained as the photopolymerization initiator, the content thereof is preferably 0.1 to 5.0 parts by mass, more preferably 0.5 to 3.0 parts by mass, further preferably 1.0 to 3.0 parts by mass, and particularly preferably 1.5 to 2.5 parts by mass relative to 100 parts by mass of the total amount of the component (A) and the component (B).

When a phosphine oxide compound is contained as the photopolymerization initiator, the content thereof is preferably 3.0 to 15 parts by mass, more preferably 3.5 to 15 parts by mass, further preferably 4.0 to 15 parts by mass, and particularly preferably 5.0 to 15 parts by mass, relative to 100 parts by mass of the total of the component (A) and the component (B).

In respect of further improving the rust prevention property of the protective film, it is preferred that the composition further comprise a triazole compound having a mercapto group, a tetrazole compound having a mercapto group, a thiadiazole compound having a mercapto group, a triazole compound having an amino group or a tetrazole compound having an amino group (hereinafter often referred to as the component (D)). As the triazole compound having a mercapto group, 3-mercapto-triazole (product name: “3MT” manufactured by Wako Pure Chemical Co., Ltd.) can be given. As the thiadiazole compound having a mercapto group, 2-amino-5-mercapto-1,3,4-thiazole (product name: “ATT” manufactured by Wako Pure Chemical Co., Ltd.) can be given, for example.

As the above-mentioned triazole compound having an amino group, a compound obtained by substation of an amino group with benzotriazole, 1H-benzotriazole-1-acetonirile, benzotriazole-5-carboxylic acid, 1H-benzotriazole-1-methanol, carboxybenzotriazole, or the like, a compound obtained by substitution of an amino group with a triazole compound having a mercapto group such as 3-mercaptotriazole and 5-mercaptotriazole, or the like can be given.

As the above-mentioned tetrazole compound having an amino group, 5-amino-1H-tetrazole, 1-methyl-5-amino-tetrazole, 1-carboxymethyl-5-amino-tetrazole, or the like can be given. These tetrazole compounds may be water-soluble salts thereof. Specific examples thereof include alkali metal salts such as salts of sodium, potassium and lithium of 1-methyl-5-amino-tetrazole.

If the composition contains the component (D), the content thereof is preferably 0.05 to 5.0 parts by mass, more preferably 0.1 to 2.0 parts by mass, further preferably 0.2 to 1.0 parts by mass, and particularly preferably 0.3 to 0.8 parts by mass, relative to 100 parts by mass of the total amount of the component (A) and the component (B).

In respect of preventing generation of residues after development, it is preferred that the photosensitive resin layer contain a phosphoric acid ester compound (hereinafter often referred to as the component (E)). In the specification of the present invention, a phosphoric acid ester compound is not included in the photopolymerizable compound as the component (B).

As the phosphoric acid ester compound as the component (E), in respect of attaining both rust prevention property of a protective film to be formed and developability at a high level, Phosmer series (Phosmer-M, Phosmer-CL, Phosmer-PE, Phosmer-MH, Phosmer-PP or the like, product name, manufactured by Uni-Chemical Co., Ltd.) or KAYAMER series (PM21, PM-2 or the like, product name, manufactured by Nippon Kayaku Co., Ltd.) are preferable.

If the component (E) is contained, the content thereof is preferably 0.05 to 5.0 parts by mass relative to 100 parts by mass of the total amount of the component (A) and the component (B), more preferably 0.1 to 2.0 parts by mass, further preferably 0.2 to 1.0 parts by mass, with 0.2 to 0.6 parts by mass being particularly preferable.

### (High-Refractive Index Layer)

The high-refractive index layer is a layer having a higher refractive index than that of the photosensitive resin layer. Meanwhile, the refractive index at a wavelength of 633 nm is normally 1.40 to 1.49.

The high-refractive index layer mentioned above has a refractive index at 633 nm of preferably 1.50 to 1.90, more preferably 1.53 to 1.85, further preferably 1.55 to 1.75. By allowing the refractive index at 633 nm of the high-refractive index layer to be 1.50 to 1.90, when a laminate shown in FIG. 2 is prepared, the refractive index becomes a value that is intermediate between a refractive index of a transparent electrode pattern 50a of ITO or the like and a refractive index of various members (e.g. OCA for adhering cover glass used for allowing it to be modular and a transparent electrode pattern) used on the photosensitive resin layer 20, whereby it becomes possible to decrease difference in color between a part where transparent electrode patterns (ITO, etc.) are formed and a part where transparent electrode patterns are not formed, and the “pattern visibility phenomenon” can be prevented. In addition, the intensity of reflected light of the entire screen can be decreased, whereby a decrease in transmittance on the screen can be prevented. The refractive index can be measured with reference to the Examples of the specification.

The refractive index of the transparent electrode such as ITO is preferably 1.80 to 2.10, more preferably 1.85 to 2.05, with 1.90 to 2.00 being further preferable. In addition, the refractive index of members such as OCA is preferably 1.45 to 1.55, more preferably 1.47 to 1.53, and further preferably 1.48 to 1.51.

The thickness of the high-refractive index layer mentioned above is preferably 10 to 500 nm, further preferably 20 to 300 nm, further preferably 30 to 250 nm, particularly preferably 40 to 200 nm, with 45 to 150 nm being significantly preferable. By allowing the film thickness to be 10 to 500 nm, the intensity of reflected light of the entire screen mentioned above can be further decreased.

It is preferred that a high-refractive index layer contain a compound having a triazine ring, a compound having an isocyanuric acid skeleton, a compound having a fluorene skeleton or a metal oxide (hereinafter also referred to as the component (F)).

In respect of refractive index and developability, patterning property, and further transparency, it is preferable to use a compound containing a triazine ring or an isocyanuric acid skeleton in combination with a compound with a fluorene skeleton.

As the compound having a triazine ring, a polymer having a triazine ring in the structural unit can be given. A compound having a structural unit represented by the following formula (8) or the like can be given.

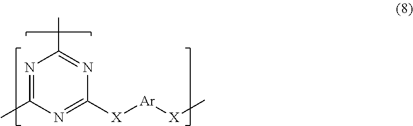

wherein Ar is a divalent group that contains at least one selected from an aromatic ring (the number of carbon atoms is 6 to 20, for example) and a heterocyclic ring (the number of atoms is 5 to 20, for example). Xs are respectively NR¹. R¹s are independently a hydrogen atom, an alkyl group (the number of carbon atoms is 1 to 20, for example), an alkoxy group (the number of carbon atoms is 1 to 20, for example), an aryl group (the number of carbon atoms is 6 to 20, for example) or an aralkyl group (the number of carbon atoms is 7 to 20, for example). Plural Xs may be the same or different.

Specifically, a hyperbranched polymer having a triazine ring is preferable. For example, it can be commercially available as HYPERTECH series (product name, manufactured by Nissan Chemical Industries, Ltd.).

This hyperbranched polymer is obtained, for example, by adding dropwise a dimethylacetamide solution of 2,4,6-trichloro-1,3,5-triazine to a dimethylacetamide solution of m-phenyldiamine to initiate polymerization and further adding dropwise 2-aminopropanol to cause a reaction, followed by precipitation in an aqueous ammonia solution.

It is possible to allow an acid value to be incorporated by modifying the resulting hyperbranched polymer having a triazine ring with phthalic acid, succinic acid, etc.

The “isocyanuric acid skeleton” of the compound having an isocyanuric acid skeleton means a group obtained by removing three hydrogen atoms from isocyanuric acid. As the compound having an isocyanuric acid skeleton, a compound represented by the following formula (9) is given.

Specifically, triallyl isocyanurate is preferable.

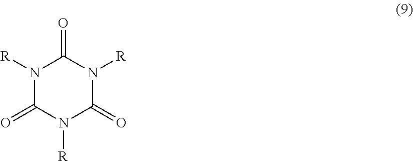

wherein Rs are independently a hydrogen atom, a halogen atom, R²OH (R² is an alkylene having 1 to 6 carbon atoms) or an aryl group, with an aryl group being preferable.

As the halogen atom, a chlorine atom is preferable.

As R²OH, a methylol group and a hydroxyethyl group are preferable.

As the compound having a fluorene skeleton, a compound having a 9,9-bis[4-2-(meth)acryloyloxyethoxy]phenyl]fluorene skeleton is preferable. The above compound may be modified with (poly)oxyethylene or (poly)oxypropylene. These are commercially available as, for example, EA-0200 (product name, manufactured by Osaka Gas Chemical Co., Ltd.). Further, it may be epoxy-modified with epoxy acrylate. These are commercially available as GA5000 or EG200 (product name, manufactured by Osaka Gas Chemical Co., Ltd.), for example.

In respect of obtaining a cured film having high transparency that has a function of improving visibility of a touch screen, it is preferred that a metal oxide be contained as the component (F).

If the component (F) contains a metal oxide, in respect of improving developability, it is preferred that a high-refractive index layer be formed by using a polymer having a carboxyl group as explained referring to the binder polymer of the photosensitive resin layer or the photopolymerizable compound having an ethylenically unsaturated group described in the photopolymerizable compound singly or in combination of two or more.

As the metal oxide, zirconium oxide, titanium oxide, tin oxide, zinc oxide, indium tin oxide, indium oxide, aluminum oxide, silicon oxide, glass and the like can be mentioned. Among these, zirconium oxide is preferable.

It is preferred that the metal oxide be in the form of fine particles.

As examples of the metal oxide, Nanouse OZ-S30K, OZ-S40K-AC, OZ-S30M (product name, manufactured by Nissan Chemical Industries, Ltd.), NANON 5ZR-010, NANON ZR-020, SZR-K, SZR-M (product name, manufactured by Sakai Chemical Industry Co., Ltd.) are commercially available.

It is preferred that zirconium oxide be used in combination with amorphous silica or tin oxide. By this, when preparing a transfer-type photosensitive refractive index adjustment film, transparency of the high-refractive index layer and developability can be further improved.

Further, it is preferred that zirconium oxide be used in combination with yttrium oxide. By this, when preparing a transfer type photosensitive refractive index adjustment film, transparency and refractive index of the high-refractive index layer can be further improved.

In Nanouse OZ-S30K, OZ-S40K-AC and OZ-S30M, amorphous silica or tin oxide is mixed other than zirconium oxide. In SZR-K and SZR-M, yttrium oxide is mixed.

Zirconium oxide or tin oxide can be specified by mapping by detecting a zirconium element, an oxygen element and a tin element by means of STEM-EDX.

The content of the component (F) in the high-refractive index layer is preferably in the following range in order to adjust the refractive index of the high-refractive index layer for light with a wavelength of 633 nm to be in a range of 1.5 to 1.9.

When a compound having a triazine ring is contained, it is preferred that the compound be contained in an amount of 10 to 100 parts by mass, more preferably 10 to 70 parts by mass, further preferably 10 to 60 parts by mass, and particularly preferably 10 to 55 parts by mass, relative to 100 parts by mass of the total amount of the component (F).

When a compound having an isocyanuric acid skeleton is contained, the compound is preferably contained in an amount of 10 to 90 parts by mass, more preferably 20 to 80 parts by mass, and further preferably 30 to 70 parts by mass, relative to 100 parts by mass of the total amount of the component (F).

When a compound having a fluorene skeleton is contained, it is preferred that the compound having a fluorene skeleton be contained in an amount of 10 to 100 parts by mass, more preferably 20 to 90 parts by mass, further preferably 30 to 90 parts by mass, and particularly preferably 40 to 90 parts by mass, relative to 100 parts by mass of the total amount of the component (F).

When a metal oxide is contained, it is preferred that the metal oxide be contained in an amount of 10 to 100 parts by mass, more preferably 20 to 93 parts by mass, and further preferably 30 to 90 parts by mass, relative to 100 parts by mass of the total amount of the component (F).

The high-refractive index layer may optionally contain one or more of the components (A) to the component (E) of the photosensitive resin layer.

The high-refractive index layer mentioned above may essentially consist of at least one of the components (F) mentioned above. That is, the high-refractive index layer of the present invention may essentially consist of the component (F).

Here, the “essentially” means that 95 mass % or more and 100 mass % or less (preferably 98 mass % or more and 100 mass % or less) of the components constituting the composition or the layer is the component (F).

The photosensitive resin layer and the high-refractive index layer of the present invention may respectively contain a known additive, according to need. As the additive, a polymerization inhibitor such as organosiloxane such as octamethylcyclotetrasiloxane, 2,2′-methylene-bis(4-ethyl-6-tert-butylphenol) can be given.

In the transfer-type photosensitive refractive index adjustment film of the present invention, the minimum value of the visible ray transmittance at 400 to 700 nm of a laminate of the photosensitive resin layer and the high-refractive index layer is preferably 90.00% or more, more preferably 90.50% or more, and further preferably 90.70% or more. If the transmittance for visible rays with a wavelength of 400 to 700 nm (that is a common visible ray wavelength region) is 90.00% or more, when a transparent electrode in a sensing region of a touch panel (touch sensor) is protected, lowering in image display quality, shade and luminance in a sensing region can be sufficiently suppressed. The maximum value of the visible ray transmittance is normally 100% or less. The visible ray transmittance can be measured with reference to the Examples of the specification.

The photosensitive resin layer 20 and the high-refractive index layer 30 of the transfer-type photosensitive refractive index adjustment film can be formed by preparing a coating liquid containing a photosensitive resin composition and a high refractive index composition containing the component (F), and then applying this liquid respectively to the supporting film 10 and the protective film 40, followed by drying to allow them to be bonded to each other. Alternatively, it can be formed by applying a coating liquid containing a photosensitive resin composition on the supporting film 10, followed by drying. Thereafter, on the photosensitive resin layer 20, a coating liquid containing a high-refractive index composition is applied, dried, followed by bonding of the protective film 40.

The coating liquid can be obtained by uniformly dissolving or dispersing in a solvent the photosensitive resin composition and the high-refractive index composition mentioned above.

No specific restrictions are imposed on a solvent used as a coating liquid, and known solvents can be used. Specific examples thereof include acetone, methyl ethyl ketone, methyl isobutyl ketone, toluene, methanol, ethanol, propanol, butanol, methylene glycol, ethylene glycol, propylene glycol, ethylene glycol monomethyl ether, ethylene glycol monoethyl ether, diethylene glycol dimethyl ether, diethylene glycol ethyl methyl ether, diethylene glycol diethyl ether, propylene glycol monomethyl ether, ethylene glycol monobutyl ether acetate, diethylene glycol monoethyl ether acetate, propylene glycol monomethyl ether acetate, chloroform, and methylene chloride.

As the coating method, doctor blade coating method, meyer bar coating method, roll coating method, screen coating method, spinner coating method, ink jet coating method, spray coating method, dip coating method, gravure coating method, curtain coating method, die coating method or the like can be given.

No specific restrictions are imposed on drying conditions. The drying temperature is preferably 60 to 130° C., and the drying time is preferably 0.5 to 30 minutes.

The total thickness of the photosensitive resin layer and the high-refractive index layer (hereinafter often referred to as a photosensitive refractive index adjustment layer) is preferably 30 μm or less, more preferably 20 μm or less, and further preferably 10 μm or less, in respect of followability at the time of laminating. Further, from the viewpoint of suppressing generation of pinholes by protrusions on the substrate, it is preferably 1 μm or more, more preferably 2 μm or more, and further preferably 3 μm or more. When it is 3 μm or more, it is easy to suppress the influence of the protrusions of the substrate as much as possible and to keep the rust prevention property.

The viscosity of the transfer-type photosensitive refractive index adjustment layer at 30° C. is preferably 15 to 100 mPa·s, more preferably 20 to 90 mPa·s, and further preferably 25 to 80 mPa·s, in respect of preventing a resin composition from oozing out from an end surface of the transfer-type photosensitive refractive index adjustment film when storing the transfer-type photosensitive refractive index adjustment film in the shape of a roll and in respect of preventing the photosensitive refractive index-layer from being too hard and breaking into pieces and preventing the broken pieces form adhering to the substrate when the transfer-type photosensitive refractive index adjustment layer is cut.

### (Protective Film)

As the protective film 40, propylene, polypropylene, polyethylene terephthalate, polycarbonate, a polyethylene-vinyl acetate copolymer, a laminate film of a polyethylene-vinyl acetate copolymer and polyethylene or the like can be given.

The thickness of the protective film 40 is preferably 5 to 100 μm. However, in respect of storing after rolling it in the form of a roll, the thickness thereof is preferably 70 μm or less, more preferably 60 μm or less, further preferably 50 μm or less, and particularly preferably 40 μm or less.

Next, an explanation will be made on a method for forming a cured film that satisfies both a function of protecting a transparent electrode by using the transfer-type photosensitive refractive index adjustment film and a function of suppressing pattern visibility phenomenon or improving visibility of a touch screen.

First, after removing a protective film 40 of a transfer-type photosensitive refractive index adjustment film 1, the transfer-type photosensitive refractive index adjustment film is crimped to the surface of the substrate 50 (a substrate with a transparent electrode pattern) such that the high-refractive index layer 30 is in close contact with the substrate 50, whereby the high-refractive index layer and the photosensitive resin layer are laminated (transferred). As the crimping means, a crimping roll can be given. A crimping roll may be provided with a heating means so as to realize crimping with heating.

As for the heating temperature when crimping with heating is conducted, in respect of adhesiveness of the high-refractive index layer 30 and the substrate 50 and also in respect of allowing components constituting the photosensitive resin layer or the high-refractive index layer to be hardly cured or decomposed by heating, the heating temperature is preferably 10 to 160° C., more preferably 20 to 150° C., and further preferably 30 to 150° C.

Further, as for the crimping pressure when crimping with heating is conducted, in respect of suppressing deformation of the substrate 50 while fully ensuring adhesiveness of the high-refractive index layer 30 and the substrate 50, a linear pressure is preferably 50 to 1×10⁵ N/m, more preferably 2.5×10² to 5×10⁴ N/m, and further preferably 5×10² to 4×10⁴ N/m.

Preheating of the substrate is not necessarily required if the transfer-type photosensitive refractive index adjustment film is crimped with heating as mentioned above. In respect of further improving adhesiveness between the high-refractive index layer 30 and the substrate 50, the substrate 50 may be subjected to preheating. At this time, the treatment temperature is preferably 30 to 150° C.

As the substrate, substrates such as a glass plate, a plastic plate and a ceramic plate used in a touch panel (touch sensor) can be given. On the substrate, an electrode on which a cured film is formed is provided. As the electrode, an electrode such as ITO, Cu, Al and Mo can be given. On the substrate, an insulating layer may be provided between the substrate and the electrode.

Next, a prescribed part of the transferred photosensitive refractive index adjustment layer is irradiated with active rays through a photomask. When irradiating active rays, if the supporting film 10 on the photosensitive refractive index adjustment layer is transparent, the photosensitive refractive index adjustment film is irradiated directly with active rays. If the supporting film 10 is not transparent, irradiation of active rays is conducted after removing the supporting film. As the light source of active rays, known sources of active rays can be used.

The irradiation amount of active rays is 1×10² to 1×10⁴ J/m². At the time of irradiation, heating can be simultaneously conducted. If the irradiation amount of the active rays is 1×10² J/m² or more, photo-curing can be sufficiently proceeded. If the irradiation amount is 1×10⁴ J/m² or less, discoloration of the photosensitive refractive index adjustment layer tends to be suppressed.

Subsequently, an unexposed part of the photosensitive resin layer and the high-refractive index layer after irradiation of active rays is removed by a developer, a refractive index adjustment pattern that covers part or all of the transparent electrode is formed. If the supporting film 10 is laminated on the photosensitive refractive index adjustment layer after irradiation of active rays, development is conducted after removing it.

Development can be conducted by known methods such as spraying, showering, immersion swinging, brushing and scrapping. Among these methods, development by spraying by using an aqueous alkaline solution is preferable in respect of environment and safety. The temperature or time of developing can be adjusted within a conventionally known range.

An electronic component according to the present embodiment is provided with a refractive index adjustment pattern formed by using the transfer-type photosensitive refractive index adjustment film. As the electronic component, a touch panel, a liquid crystal display, an organic electronic luminescence device, a solar battery module, a print circuit board, electronic paper or the like can be given.

FIG. 3 is a schematic top view showing one example of a capacitive touch panel. The touch panel shown in FIG. 3 has a touch screen 102 for detecting touch position detection coordinates on one side of a transparent substrate 101. A transparent electrode 103 and a transparent electrode 104 are provided on the substrate 101 in order to detect a change in electrostatic capacitance in this region.

A transparent electrode 103 and a transparent electrode 104 respectively detect the X-position coordinate and the Y-position coordinate of the touch position.

On the transparent substrate 101, a lead-out wiring 105 for transmitting detected signals of the touch position from the transparent electrode 103 and the transparent electrode 104 to external circuits is provided. The lead-out wiring 105 and the transparent electrode 103 and the transparent electrode 104 are connected by a connection electrode 106 provided on the transparent electrode 103 and the transparent electrode 104. On an end part opposite to the connection part of the transparent electrode 103 and the transparent electrode 104 of the lead-out wiring 105, a connection terminal 107 for connection with external circuits is provided.

As shown in FIG. 3, by forming a refractive index adjustment pattern 123, a function as a protective film of the transparent electrode 103, the transparent electrode 104, the lead-out wiring 105, the connection electrode 106 and the connection terminal 107, and a function of adjusting the refractive index of a sensing region (touch screen 102) formed of the transparent electrode pattern are simultaneously attained.

### EXAMPLES

Hereinbelow, the present invention will be explained in more detail with reference to the Examples, which should not be construed as limiting the scope of the invention.

### [Preparation of a Binder Polymer Solution (A1)]

In a flask provided with a stirrer, a reflux condenser, an inert gas introduction port and a thermometer, the components (1) shown in Table 1 were charged, and heated to 80° C. in a nitrogen gas atmosphere. While keeping the reaction temperature to 80° C.±2° C., the component (2) shown in Table 1 were added dropwise homogenously for 4 hours. After dropwise addition of the component (2), stirring was conducted at 80° C.±2° C. for 6 hours, whereby a solution (solid matter content: 45 mass %) of a binder polymer having a weight-average molecular weight of 65,000, an acid value of 78 mgKOH/g and a hydroxyl value of 2 mgKOH/g was obtained (A1).

TABLE 1

| | | Blend amount (parts by mass) |
|---|---|---|
| | | (A1) |
| (1) | Propylene glycol | 62 |
| | monomethyl ether | |
| | Toluene | 62 |
| (2) | Methacrylic acid | 12 |
| | Methyl methacrylate | 58 |
| | Ethyl acrylate | 30 |
| | 2,2-azobis | 1.5 |
| | (isobutyronitrile) | |

| | |
|---|---|
| Weight-average molecular weight | 65,000 |
| Hydroxyl value (mgKOH/g] | 2 |
| Acid value (mgKOH/g) | 78 |
| Tg(° C.) | 60 |

The weight-average molecular weight (Mw) was measured by gel permeation chromatography (GPC) and converted by a calibration line of standard polystyrene. Conditions of GPC are shown below.

### <GPC Conditions>

Pump: L-6000 (product name, manufactured by Hitachi, Ltd.)

Column: Gelpack GL-R420, Gelpack GL-R430, Gelpack GL-R440, product names, all are manufactured by Hitachi Chemical Co., Ltd.)

Eluent: Tetrahydrofuran

Measurement temperature: 40° C.

Flow rate: 2.05 mL/min

Detector: L-3300 (product name, RI detector, manufactured by Hitachi, Ltd.)

### [Method for Measuring Acid Value]

The binder polymer solution was heated at 130° C. for 1 hour, and volatile matters were removed to obtain solid matters. Then, 1 g of the solid polymer was preciously weighed. 30 g of acetone was added to this polymer, and the polymer was uniformly dissolved therein. Subsequently, an appropriate amount of phenolphthalein as an indicator was added thereto, and titration was conducted by using a 0.1N KOH aqueous solution. An acid value was calculated by the following formula:

Acid value=0.1×Vf×56.1/(Wp×I/100)

In the formula, Vf shows a titration amount (mL) of an aqueous solution of KOH, Wp is a mass (g) of the resin solution measured, and I is a ratio (mass %) of non-volatile matters in the resin solution measured.

### [Method for Measuring Hydroxyl Value]

The binder polymer solution was heated at 130° C. for 1 hour, and volatile matters were removed to obtain solid matters. 1 g of the solid matters were preciously weighed, and the polymer was put in an Erlenmeyer flask. 10 mL of a 10 mass % anhydrous acetic pyridine solution was added, and heated at 100° C. for 1 hour. After the heating, 10 mL of water and 10 mL of pyridine were added, and heated at 100° C. for 10 minutes. Thereafter, by using an automatic titrator (product name: “COM-1700” manufactured by Hiranuma Sangyo Co., Ltd.), neutralization titration was conducted with 0.5 mol/L of an ethanol solution of potassium hydroxide. The hydroxyl value was calculated by the following formula:

Hydroxyl value=(A−B)×f×28.05/sample(g)+acid value

In the formula, A is the amount (mL) of the 0.5 mol/L-ethanol solution of potassium hydroxide used for a blank test, B is the amount (mL) of the 0.5 mol/L-ethanol solution of potassium hydroxide used for titration and f is a factor.

### [Preparation of Binder Polymer Solution (A2)]

Synthesis was conducted in the same manner as in the case of the binder polymer solution (A1), except that the component (2) shown in Table 1 was changed to 12 parts by mass of methacrylic acid, 38 parts by mass of methyl methacrylate, 30 parts by mass of ethyl acrylate, 20 parts by mass of cyclohexyl methacrylate and 1.1 parts by mass of 2,2′-azobis(isobutylonitrile), whereby a solution (A2) of a binder polymer (solid matter content: 45 mass %) having a weight-average molecular weight of 65,000, an acid value of 78 mgKOH/g and a hydroxyl value of 2 mgKOH/g was obtained.

### [Preparation of Binder Polymer Solution (A3)]

Synthesis was conducted in the same manner as in the case of the binder polymer solution (A1), except that the component (2) shown in Table 1 was changed to 24 parts by mass of methacrylic acid, 44 parts by mass of methyl methacrylate, 15 parts by mass of butyl acrylate, 17 parts by mass of butyl methacrylate and 3 parts by mass of 2,2′-azobis(isobutylonitrile), whereby a solution (A3) of a binder polymer (solid matter content: 45 mass %) having a weight-average molecular weight of 25,000, an acid value of 157 mgKOH/g and a hydroxyl value of 2 mgKOH/g was obtained.

### [Preparation of Binder Polymer Solution (A4)]

Synthesis was conducted in the same manner as in the case of the binder polymer solution (A1), except that the component (2) shown in Table 1 was changed to 30 parts by mass of methacrylic acid, 22 parts by mass of methyl methacrylate, 10 parts by mass of butyl acrylate, 8 parts by mass of butyl methacrylate, 30 parts by mass of styrene and 1.1 parts by mass of 2,2′-azobis(isobutylonitrile), whereby a solution (A4) of a binder polymer (solid matter content: 45 mass %) having a weight-average molecular weight of 50,000, an acid value of 196 mgKOH/g and a hydroxyl value of 2 mgKOH/g was obtained.

### Examples 1 to 24 and Comparative Examples 1 to 19

### [Preparation of Coating Liquid for Forming Photosensitive Resin Layer]

The compositions shown in the columns of the “photosensitive resin layer” in Tables 2 to 5 were mixed for 15 minutes by using a stirrer, whereby coating liquids for forming a photosensitive resin layer were prepared.

### [Preparation of Coating Film for Forming High-Refractive Layer]

The components in the “high-refractive layer” in Tables 2 to 5 were mixed for 15 minutes by means of a stirrer, whereby a coating liquid for forming a high-refractive layer was prepared.

The numerical symbols for the components in Tables 2 to 5 have the following meanings.

### Component (A)

(A1) Propylene glycol monomethyl ether/toluene solution of a copolymer having a monomer compounding ratio (methacrylic acid/methyl methacrylate/ethyl acrylate=12/58/30 (mass ratio), weight average molecular weight 65,000, acid value 78 mgKOH/g, hydroxyl value 2 mgKOH/g, Tg 60° C.
(A2) Propylene glycol monomethyl ether/toluene solution of a copolymer having a monomer compounding ratio (methacrylic acid/methyl methacrylate/ethyl acrylate/cyclohexyl methacrylate=12/38/30/20 (mass ratio)), weight average molecular weight 65,000, acid value 78 mgKOH/g, hydroxyl value 2 mgKOH/g, Tg 54° C.
(A3) Propylene glycol monomethyl ether/toluene solution of a copolymer having a monomer compounding ratio (methacrylic acid/methyl methacrylate/butyl acrylate/butyl methacrylate=24/44/15/17 (mass ratio)), weight average molecular weight 25,000, acid value 157 mgKOH/g, hydroxyl value 2 mgKOH/g, Tg 65° C.
(A4) Propylene glycol monomethyl ether/toluene solution of a copolymer having a monomer compounding ratio (methacrylic acid/methyl methacrylate/ethyl acrylate/butyl methacrylate/styrene=30/22/10/8/30 (mass ratio)), weight average molecular weight 50,000, acid value 196 mgKOH/g, hydroxyl value 2 mgKOH/g, Tg 96° C.

### Component (B)

T-1420 (T): Ditrimethylol propane tetracrylate (product name, manufactured by Nippon Kayaku Co., Ltd.)
FA321M: (Meth)acrylic compound/bisphenol AEO modified dimethacrylate (product name, manufactured by Hitachi Chemical, Co. Ltd.)

### Component (C)

IRGACURE OXE 01: 1,2-octanedione, 1-[(4-phenylthio)phenyl, 2-(O-benzoyloxime)](product name, manufactured by BASF Japan Ltd.)
IRGACURE 379: 2-(dimethylamino)-2-[(4-methylphenyl)methyl]-1-[4-(4-morpholinyl)phenyl]-1-butanone (product name, manufactured by BASF Japan Ltd.)
DETX: 2,4-diethylthioxanthone (product name, manufactured by Nippon Kayaku Co., Ltd.)
TPO: 2,4,6-trimethylbenzoyl-diphenyl-phosphine oxide (product name “LUCIRIN TPO” manufactured by BASF Japan Ltd.)

### Component (D)

HAT: 5-amino-1H-tetrazole (product name, manufactured by Toyobo Co., Ltd.)
3MT: 3-mercapto-triazole (product name, manufactured by Wako Pure Chemical, Co., Ltd.)

### Component (E)

PM-21: Phosphoric acid ester including a photopolymerizable unsaturated bond (product name, manufactured by Nippon Kayaku Co., Ltd.)
Phosmer-M: 2-(methacryloyloxy)ethyl phosphate (product name, manufactured by Unichemical Co., Ltd.)

### Component (F)

UR 658: Polymer having a triazine skeleton (product name “HYPERTECH series UR 658” (trade name) manufactured by Nissan Chemical Industries, Ltd.)
Triallyl isocyanurate: manufactured by Tokyo Chemical Industry Co., Ltd.
OZ-S40 K-AC: Zirconia dispersion (product name “Nano-use OZ-S40K-AC” manufactured by Nissan Chemical Industries, Ltd.)
OZ-S30K: Zirconia dispersion liquid (product name “Nano-use OZ-S30K” manufactured by Nissan Chemical Industries, Ltd.)
EA0200: Polyoxyethylene-modified 9,9-bis (4-hydroxyphenyl) fluorenediacrylate (product name, manufactured by Osaka Gas Chemicals Co., Ltd.)
EAF 5503: A mixture of polyoxyethylene-modified 9,9-bis(4-hydroxyphenyl) fluorenediacrylate/benzyl acrylate/9,9-bis(4-hydroxyphenyl) fluorene skeleton compound (product name, manufactured by Osaka Gas Chemicals Co.)
EA-HC 931: Polyoxyethylene-modified 9,9-bis (4-hydroxyphenyl) fluorenediacrylate and other mixture (product name, manufactured by Osaka Gas Chemicals Co., Ltd.)

Other Components
Antage W-500: 2,2′-methylene-bis(4-ethyl-6-tert-butylphenol) (product name, manufactured by Kawaguchi Chemical Industry Co., Ltd.)
SH-30: Octamethylcyclotetrasiloxane (product name, manufactured by Dow Corning Toray Co., Ltd.) Methyl ethyl ketone (manufactured by Tonen Chemical Corporation)
L-7001: Octamethylcyclotetrasiloxane (product name, manufactured by Dow Coming Toray Co., Ltd.)

### [Preparation of Transfer-Type Photosensitive Refractive Index Adjustment Film]

As the protective film, a 30 μm-thick polyethylene terephthalate film (product name: “E-201F” manufactured by Oji F-Tex Co., Ltd,) was used. The coating liquid prepared above for forming the high-refractive layer was uniformly applied onto a protective film by using a die coater, and dried for 3 minutes in a hot air convection drier of 100° C. to remove the solvent, whereby a high-refractive layer was formed.

As the supporting film, a 16 μm-thick polyethylene terephthalate film (product name: “FB40” manufactured by Toray Industries, Inc.) was used. The coating liquid prepared above for forming the photosensitive resin layer was uniformly applied onto a protective film by using a comma coater, and dried for 3 minutes in a hot air convection drier of 100° C. to remove the solvent, whereby an 8 μm-thick photosensitive resin layer was formed.

The protective film prepared above having the high-refractive layer and the supporting film prepared above having the photosensitive resin layer were laminated by means of a laminator (product name: “HLM-3000”, manufactured by Hitachi Chemical Co., Ltd.) at 23° C., whereby a transfer-type photosensitive refractive index adjustment film was prepared.

For the transfer-type photosensitive refractive index adjustment film or each constituent layer, the following items were evaluated. The results are shown in Tables 2 to 5.

### [Measurement of Refractive Index of High-Refractive Index Layer]

A coating liquid for forming the high-refractive index layer prepared above was uniformly applied onto a 0.7 mm-thick glass substrate by means of a spin coater, and dried for 3 minutes in a hot air convention drier of 100° C. to remove the solvent, whereby a high-refractive index layer was formed.

Subsequently, the obtained high-refractive index layer was irradiated with UV rays by means of a parallel ray exposure apparatus (product name: “EXM1201” manufactured by Oak Manufacturing Co., Ltd.) at an exposure amount of 5×10² J/m² (measurement value at 365 nm). Then, the sample was allowed to stand for 30 minutes in a box dryer (model number: “NV50-CA” manufactured by Mitsubishi Electric Corporation) heated to 140° C., thereby to obtain a sample for refractive index measurement having a high-refractive index layer.

Subsequently, the obtained refractive index measurement sample was measured for the refractive index at 633 nm with ETA-TCM (product name, manufactured by AudioDev GmbH, Co., Ltd.).

The refractive index of the single layer of the refractive index layer in the form of the transfer-type photosensitive refractive index adjustment film is the value of the outermost surface layer of the high-refractive index layer on the support film side.

### [Measurement of Film Thickness of High-Refractive Index Layer and Photosensitive Resin Layer]

The protective film having the high-refractive index layer and the support film having the photosensitive resin layer were measured before being bonded to each other. The film thickness of the high-refractive index layer was measured by measuring the high-refractive index layer of the protective film having the high-refractive index layer prepared above by using F20 (product name, manufactured by FILMETRICS Co., Ltd.). The film thickness of the photosensitive resin layer was measured by measuring the support film having the photosensitive resin layer prepared above by using a digital thickness gauge (product name: “DIGIMICROSTAND MS-5C” manufactured by Nikon Corporation).

### [Measurement of b* of Cured Film]

While peeling off the protective film of the obtained transfer-type photosensitive refractive index adjustment film, on a 0.7 mm-thick glass substrate, lamination was conducted by using a laminator (product name: “HLM-3000”, manufactured by Hitachi Chemical Co., Ltd.) such that the high-refractive layer was brought into contact therewith under conditions of roll temperature of 120° C., substrate supply speed of 1 m/min and crimping pressure (cylinder pressure) of 4×10⁵ Pa (since a substrate having a thickness of 1 mm and a vertical length of 10 cm and a lateral length of 10 cm was used, the linear pressure at the time of the lamination was 9.8×10³ N/m), whereby a laminate in which the high-refractive layer, the photosensitive resin layer and the supporting film were stacked on the glass substrate was obtained.

Subsequently, the obtained laminate was irradiated with UV rays by means of a parallel ray exposure apparatus (product name: “EXM1201” manufactured by Oak Manufacturing Co., Ltd.) from the upper side of the photosensitive resin layer with an exposure amount of 5×10² J/m² (measured value with i rays (wavelength: 365 nm)). Thereafter, the supporting film was removed, and the laminate was further irradiated with UV rays from the upper side of the photosensitive resin layer with an exposure amount of 1×10⁴ J/m² (measured value with i rays (wavelength: 365 nm)), whereby a sample having an 8 μm-thick cured film of the photosensitive resin layer was obtained.

Subsequently, by using a spectral colorimeter (product name: “CM-5” manufactured by Konica Minolta Japan, Inc.), b* (transmitted b* and reflected b*) in a CIELAB color system at a light source setting D65 and a viewing angle of 2° was measured.

For reference, the measurement values of the glass substrate single body are shown in Table 5.

### [Measurement of Hue (Reflectance R)]

While peeling off the protective film of the obtained transfer-type photosensitive refractive index adjustment film, on a transparent conductive film (product name: “300R”, manufactured by Toyobo Co., Ltd.), lamination was conducted by using a laminator (product name: “HLM-3000”, manufactured by Hitachi Chemical Co., Ltd.) such that the high-refractive layer was brought into contact therewith under conditions of roll temperature of 120° C., substrate supply speed of 1 m/min and crimping pressure (cylinder pressure) of 4×10⁵ Pa (since a substrate having a thickness of 1 mm and a vertical length of 10 cm and a lateral length of 10 cm was used, the linear pressure at the time of the lamination was 9.8×10³ N/m), whereby a laminate in which the high-refractive layer, the photosensitive resin layer and the supporting film were stacked on the glass substrate was obtained.

Subsequently, the obtained laminate was irradiated with UV rays by means of a parallel ray exposure apparatus (product name: “EXM1201” manufactured by Oak Manufacturing Co., Ltd.) from the upper side of the photosensitive resin layer with an exposure amount of 5×10² J/m² (measured value at a wavelength of 365 nm). Thereafter, the supporting film was removed, whereby a sample for measuring a hue (reflectance R) having a cured film was obtained.

Subsequently, by using a spectral colorimeter (product name: “CM-5” manufactured by Konica Minolta Japan, Inc.), in a manner that there was a light source on the photosensitive resin layer side, the Y value (this is taken as the reflectance R) of the obtained sample for measuring hue in the XYZ color system was measured at a light source setting of D65, a viewing angle of 2°, measuring diameter of 30 mm φ, and by the SCI (specular reflection light inclusion) method, and standardization was conducted by using the following formula:

Standardization of the reflectance R=Actual measured value of the reflectance/Actual measured value of the reflectance of the measurement sample in which only the photosensitive resin layer was laminated (Comparative Example 16)×100

For reference, the measurement values of the transparent conductive film single body are shown in Table 5.

### [Salt Spray Test on Cured Film (Test for Evaluating Resistance to Synthetic Sweat)]

While peeling off the protective film of the obtained transfer-type photosensitive refractive index adjustment film, on a polyimide film provided with sputtering copper (manufactured by Toyobo Co., Ltd.), lamination was conducted by using a laminator (product name: “HLM-3000”, manufactured by Hitachi Chemical Co., Ltd.) such that the high-refractive layer was brought into contact therewith under conditions of roll temperature of 120° C., substrate supply speed of 1 m/min and crimping pressure (cylinder pressure) of 4×10⁵ Pa (since a substrate having a thickness of 1 mm and a vertical length of 10 cm and a lateral length of 10 cm was used, the linear pressure at the time of the lamination was 9.8×10³ N/m), whereby a laminate in which the high-refractive layer, the photosensitive resin layer and the supporting film were stacked on the sputtering copper was obtained.

Subsequently, the obtained laminate was irradiated with UV rays by means of a parallel ray exposure apparatus (product name: “EXM1201” manufactured by Oak Manufacturing Co., Ltd.) from the upper side of the photosensitive resin layer with an exposure amount of 5×10² J/m² (measured value at a wavelength of 365 nm). Thereafter, the supporting film was removed, and the laminate was irradiated with UV rays with an exposure amount of 1×10⁴ J/m² (measured value at a wavelength of 365 nm) and left for 30 minutes at 140° C. in a box-type dryer (model: “NV50-CA”, manufactured by Mitsubishi Electric Corporation), whereby a sample for measuring the resistance for synthetic sweat was obtained.

Subsequently, in accordance with the JIS standard (Z2371), the sample was mounted on a test chamber by using a salt water spray tester (product name: “STP-90 V2” manufactured by Suga Test Instruments Co., Ltd.). Salt water (pH=6.7) with a concentration of 50 g/L was sprayed for 48 hours with a temperature of the test chamber of 35° C. and a spray amount of 1.5 mL/h. After spraying, the salt water was wiped off, and the surface condition of the sample of evaluation was observed, and evaluation was conducted in accordance with the following evaluation criteria:
A: No change on the surface of the protective film
B: Slight amount of traces were observed on the surface of the protective film, but no change was observed in copper
C: Traces were observed on the surface of the protective film, but no change was observed in copper
D: Traces were observed on the surface of the protective film and copper was discolored

For reference, the measured value of the polyimide film provided with sputtering copper single body is shown in Table 5.

### [Measurement of Transmittance (%) and Haze of Cured Film]

While peeling off the protective film of the transfer-type photosensitive refractive index control film prepared above, a laminate was prepared by means of a laminator (product name: “HLM-3000 type” manufactured by Hitachi Chemical Co., Ltd.) on a glass substrate having a thickness of 0.7 mm so that the high-refractive index layer was in contact therewith under conditions where a roll temperature of 120° C., a substrate feed rate of 1 m/min and a crimping pressure (cylinder pressure) of 4×10⁵ Pa (since a substrate having a thickness of 1 mm and a vertical length of 10 cm and a lateral length of 10 cm was used, the linear pressure at the time of the lamination was 9.8×10³ N/m) to produce a laminate in which a high-refractive index layer, a photosensitive resin layer and a supporting film were laminated on a glass substrate.

Subsequently, the obtained laminate was irradiated with UV rays by means of a parallel ray exposure apparatus (product name: “EXM1201”, manufactured by Oak Manufacturing Co., Ltd.) from the upper side of the photosensitive resin layer with an exposure amount of 5×10² J/m² (measured value at a wavelength of 365 nm). Thereafter, the supporting film was removed, and left for 30 minutes at 140° C. in a box-type dryer (model: “NV50-CA”, manufactured by Mitsubishi Electric Corporation), whereby a sample for measuring the transmittance was obtained.

Subsequently, for the obtained sample for measuring the transmittance, visible ray transmittance and haze value were measured at a measurement wavelength region of 400 to 700 nm by means of a haze meter (product name: “NDH 7000”, manufactured by Nippon Denshoku Industries, Co., Ltd.).

For reference, the measured value of the glass substrate single body is shown in Table 5.

[Test on Residues after Development]

While peeling off the protective film of the resulting transfer-type photosensitive refractive index adjustment film prepared above, on a PET film provided with an easily-adherable layer (product name: “A4300” manufactured by Toyobo Co., Ltd. having a thickness of 125 μm), lamination was conducted by using a laminator (product name: “HLM-3000” manufactured by Hitachi Chemical Co., Ltd.) such that the high-refractive layer was brought into contact therewith under conditions of roll temperature of 120° C., substrate supply speed of 1 m/min and crimping pressure (cylinder pressure) of 4×10⁵ Pa (since a substrate having a thickness of 125 μm and a vertical length of 10 cm and a lateral length of 10 cm was used, the linear pressure at the time of the lamination was 9.8×10³ N/m), whereby a laminate in which the high-refractive layer, the photosensitive resin layer and the supporting film were laminated on the A4300 was obtained.

After preparing the laminate as above, the laminate was stored at a temperature of 23° C. and humidity of 60% for 30 minutes. Thereafter, the supporting film laminated on the photosensitive resin layer was removed, and development was conducted by using an aqueous 1.0 mass % sodium carbonate solution at 30° C. for 40 seconds, whereby the high-refractive index layer and the photosensitive resin layer were removed. The state of the surface of the resulting substrate was observed by a microscope, and the development residues were evaluated in accordance with the following evaluation criteria:
A: No development residues are generated
B: Slight amount of development residues were generated, but no influences are exerted on the steps afterwards
C: Development residues are generated
D: A large amount of development residues are generated

TABLE 2

| | | | Ex. | Ex. | Ex. | Ex. | Ex. | Ex. | Ex. | Ex. |
|---|---|---|---|---|---|---|---|---|---|---|
| | | | 1 | 2 | 3 | 4 | 5 | 6 | 7 | 8 |
| Photo- | Component (A) | A1 | 16 | 16 | 16 | 16 | 60 | 60 | 60 | 60 |
| sensitive | | A2 | — | — | — | — | — | — | — | — |
| resin | Component (B) | T-1420(T) | 40 | 40 | 40 | 40 | 40 | 40 | 40 | 40 |
| layer | Component (C) | IRGACURE | 1.7 | 1.7 | 1.7 | 1.7 | 1.7 | 1.7 | 1.7 | 1.7 |
| | | OXE 01 | | | | | | | | |
| | | TPO | — | — | — | — | — | — | — | — |
| | Component (D) | HAT | 0.4 | 0.4 | 0.4 | 0.4 | 0.4 | 0.4 | 0.4 | 0.4 |
| | Component (E) | PM-21 | 0.5 | 0.5 | 0.5 | 0.5 | 0.25 | 0.25 | 0.25 | 0.25 |
| | Others | Antage | 0.1 | 0.1 | 0.1 | 0.1 | 0.1 | 0.1 | 0.1 | 0.1 |
| | | W-500 | | | | | | | | |
| | | SH-30 | 0.07 | 0.07 | 0.07 | 0.07 | 0.07 | 0.07 | 0.07 | 0.07 |
| | | Methyl ethyl | 50 | 50 | 50 | 50 | 50 | 50 | 50 | 50 |
| | | ketone | | | | | | | | |
| High | Component (F) | UR658 | 50 | 50 | 50 | 50 | 50 | 50 | 50 | 50 |
| refractive | | Trially | — | — | — | — | — | — | — | — |
| index | | isocyanurate | | | | | | | | |
| layer | | EAF5503 | 50 | 50 | 50 | 50 | 50 | 50 | 50 | 50 |
| | Others | L-7001 | 1 | 1 | 1 | 1 | 1 | 1 | 1 | 1 |

| Refractive index of high refractive | | 1.62 | 1.62 | 1.62 | 1.62 | 1.62 | 1.62 | 1.62 | 1.62 |
|---|---|---|---|---|---|---|---|---|---|
| indexlayer@λ633 nm | | | | | | | | | |
| Film thickness of high refractive | | 90 | 100 | 110 | 125 | 140 | 175 | 185 | 195 |
| indexlayer (nm) | | | | | | | | | |
| Film thickness of photosensitive resin | | 8 | 8 | 8 | 8 | 8 | 8 | 8 | 8 |
| layer (μm) | | | | | | | | | |
| Transmission | b* | 1.18 | 1.15 | 1.13 | 1.13 | 1.09 | 1.22 | 1.32 | 1.41 |
| Reflectance | Y | 8.55 | 8.50 | 8.25 | 8.19 | 7.97 | 7.60 | 7.67 | 7.70 |
| | b* | −0.24 | −0.22 | 0.01 | −0.04 | 0.22 | −0.30 | −1.00 | −1.48 |

| | | | | | | | | |
|---|---|---|---|---|---|---|---|---|
| Salt water spray test | A | A | A | A | A | A | A | A |
| Transmittance (%) | 90.72 | 90.82 | 91.01 | 91.07 | 91.29 | 91.59 | 91.45 | 91.48 |
| Haze | 0.47 | 0.38 | 0.65 | 0.75 | 0.60 | 0.49 | 0.39 | 0.44 |
| Development residue test | A | A | A | A | A | A | A | A |
| Standardization of reflectance R | 89.76% | 89.19% | 86.56% | 85.93% | 83.62% | 79.74% | 80.47% | 80.79% |

| | | | Ex. | Ex. | Ex. | Ex. | Ex. | Ex. |
|---|---|---|---|---|---|---|---|---|
| | | | 9 | 10 | 11 | 12 | 13 | 14 |
| Photo- | Component (A) | A1 | 60 | 60 | — | 60 | 60 | 60 |
| sensitive | | A2 | — | — | 60 | — | — | — |
| resin | Component (B) | T-1420(T) | 40 | 40 | 40 | 40 | 40 | 40 |
| layer | Component (C) | IRGACURE | 1.7 | 1.7 | 1.7 | — | 1.7 | 1.7 |
| | | OXE 01 | | | | | | |
| | | TPO | — | — | — | 10 | — | — |
| | Component (D) | HAT | 0.4 | 0.4 | 0.4 | 0.4 | 0.4 | 0.4 |
| | Component (E) | PM-21 | 0.5 | 0.5 | 0.25 | 0.25 | 0.5 | 0.5 |
| | Others | Antage | 0.1 | 0.1 | 0.1 | 0.1 | 0.1 | 0.1 |
| | | W-500 | | | | | | |
| | | SH-30 | 0.07 | 0.07 | 0.07 | 0.07 | 0.07 | 0.07 |
| | | Methyl ethyl | 50 | 50 | 50 | 50 | 50 | 50 |
| | | ketone | | | | | | |
| High | Component (F) | UR658 | 50 | 50 | 50 | 50 | — | 50 |
| refractive | | Trially | — | — | — | — | 50 | — |
| index | | isocyanurate | | | | | | |
| layer | | EAF5503 | 50 | 50 | 50 | 50 | 50 | 50 |
| | Others | L-7001 | 1 | 1 | 1 | 1 | 1 | 1 |

| Refractive index of high refractive | | 1.62 | 1.62 | 1.62 | 1.62 | 1.60 | 1.62 |
|---|---|---|---|---|---|---|---|
| indexlayer@λ633 nm | | | | | | | |
| Film thickness of high refractive | | 205 | 220 | 220 | 220 | 220 | 220 |
| indexlayer (nm) | | | | | | | |
| Film thickness of photosensitive resin | | 8 | 8 | 8 | 8 | 8 | 8 |
| layer (μm) | | | | | | | |
| Transmission | b* | 1.48 | 1.62 | 1.60 | 1.32 | 1.48 | 1.62 |
| Reflectance | Y | 7.68 | 7.70 | 7.70 | 8.06 | 7.65 | 7.69 |
| | b* | −1.76 | −2.54 | −2.55 | −1.49 | −2.49 | −2.50 |

| | | | | | | |
|---|---|---|---|---|---|---|
| Salt water spray test | A | A | A | A | A | A |
| Transmittance (%) | 91.54 | 91.26 | 91.30 | 90.60 | 91.43 | 91.00 |
| Haze | 0.55 | 0.60 | 0.58 | 0.31 | 0.42 | 0.43 |
| Development residue test | A | A | A | A | A | A |
| Standardization of reflectance R | 80.63% | 80.79% | 80.84% | 84.57% | 80.31% | 80.73% |

TABLE 3

| | | | Ex. | Ex. | Ex. | Ex. | Ex. | Ex. | Ex. | Ex. | Ex. | Ex. |
|---|---|---|---|---|---|---|---|---|---|---|---|---|
| | | | 15 | 16 | 17 | 18 | 19 | 20 | 21 | 22 | 23 | 24 |
| Photo- | Component (A) | A1 | 60 | 60 | 60 | 60 | 60 | 60 | 60 | 60 | 60 | 60 |
| sensitive | Component (B) | T-1420(T) | 40 | 40 | 40 | 40 | 40 | 40 | 40 | 40 | 40 | 40 |
| resin | Component (C) | IRGACURE | 1.7 | 1.7 | 1.7 | 1.7 | 1.7 | 1.7 | 1.7 | 1.7 | 1.7 | 1.7 |
| layer | | OXE 01 | | | | | | | | | | |
| | Component (D) | HAT | 0.4 | 0.4 | 0.4 | 0.4 | 0.4 | 0.4 | 0.4 | 0.4 | 0.4 | 0.4 |
| | Component (E) | PM-21 | 0.5 | 0.5 | 0.5 | 0.5 | 0.5 | 0.5 | 0.5 | 0.5 | 0.5 | 0.5 |
| | Others | Antage | 0.1 | 0.1 | 0.1 | 0.1 | 0.1 | 0.1 | 0.1 | 0.1 | 0.1 | 0.1 |
| | | W-500 | | | | | | | | | | |
| | | SH-30 | 0.07 | 0.07 | 0.07 | 0.07 | 0.07 | 0.07 | 0.07 | 0.07 | 0.07 | 0.07 |
| | | Methyl ethyl | 50 | 50 | 50 | 50 | 50 | 50 | 50 | 50 | 50 | 50 |
| | | ketone | | | | | | | | | | |
| High | Component (A) | A3 | — | — | — | 7.0 | 8.0 | 8.8 | 10.5 | 12.0 | 7.0 | — |
| refractive | | A4 | — | — | — | — | — | — | — | — | — | 11.0 |
| index | Component (B) | FA321M | 3.5 | 3.7 | 3.8 | 7.0 | 8.0 | 8.8 | 10.5 | 12.0 | 7.0 | 3.0 |
| layer | Component (D) | HAT | — | — | — | 0.3 | 0.3 | 0.4 | 0.4 | 0.5 | 0.3 | 0.3 |
| | Component (E) | PM-21 | 0.4 | 0.4 | 0.4 | 0.3 | 0.3 | 0.4 | 0.4 | 0.5 | 0.3 | 0.3 |
| | Component (F) | UR658 | 14.2 | 11.0 | 7.6 | — | — | — | — | — | — | — |
| | | OZ-S30K | 79.8 | 82.7 | 85.9 | 84.0 | 82.0 | 80.0 | 76.0 | 72.0 | 84.0 | 84.0 |
| | Others | L-7001 | 2.1 | 2.2 | 2.3 | 1.7 | 2.0 | 2.0 | 2.5 | 3.0 | 1.7 | 1.7 |

| Refractive index of high refractive | | 1.65 | 1.65 | 1.64 | 1.63 | 1.63 | 1.62 | 1.62 | 1.61 | 1.63 | 1.63 |
|---|---|---|---|---|---|---|---|---|---|---|---|
| indexlayer@λ633 nm | | | | | | | | | | | |
| Film thickness of high refractive | | 100 | 100 | 100 | 80 | 80 | 80 | 80 | 80 | 80 | 80 |
| indexlayer (nm) | | | | | | | | | | | |
| Film thickness of photosensitive resin | | 8 | 8 | 8 | 8 | 8 | 8 | 8 | 8 | 8 | 8 |
| layer (μm) | | | | | | | | | | | |
| Trasmittance | b* | 1.41 | 1.43 | 1.43 | 1.33 | 1.24 | 1.25 | 1.36 | 1.40 | 1.41 | 1.16 |
| Reflectance | Y | 7.80 | 7.79 | 7.78 | 7.91 | 7.89 | 7.86 | 7.97 | 7.93 | 7.95 | 7.90 |
| | b* | −2.43 | −2.72 | −2.42 | −3.09 | −2.90 | −2.28 | −3.33 | −2.55 | −3.28 | −3.30 |

| | | | | | | | | | | |
|---|---|---|---|---|---|---|---|---|---|---|
| Salt water spray test | A | A | A | A | A | A | A | A | A | A |
| Transmittance (%) | 91.21 | 91.14 | 91.14 | 90.88 | 91.02 | 90.98 | 91.04 | 91.00 | 90.56 | 90.96 |
| Haze | 0.47 | 0.50 | 0.50 | 0.40 | 0.41 | 0.42 | 0.40 | 0.40 | 0.41 | 0.40 |
| Development residue test | A | A | A | A | A | A | A | A | A | A |
| Standardization of reflectance R | 81.80% | 81.80% | 81.70% | 83.04% | 82.83% | 82.52% | 83.67% | 83.25% | 83.46% | 82.94% |

TABLE 4

| | | | Comp. | Comp. | Comp. | Comp. | Comp. | Comp. | Comp. | Comp. | Comp. |
|---|---|---|---|---|---|---|---|---|---|---|---|
| | | | Ex. 1 | Ex. 2 | Ex. 3 | Ex. 4 | Ex. 5 | Ex. 6 | Ex. 7 | Ex. 8 | Ex. 9 |
| Photo- | Component (A) | A1 | 60 | 60 | 60 | 60 | 60 | 60 | 60 | 60 | 60 |
| sensitive | Component (B) | T-1420(T) | 40 | 40 | 40 | 40 | 40 | 40 | 40 | 40 | 40 |
| resin | Component (C) | IRGACURE | 1.9 | 3.7 | 5.6 | 1.7 | 1.7 | 1.9 | 5.6 | 1.7 | 1.7 |
| layer | | 379 | | | | | | | | | |
| | | DETX | 1.9 | 3.7 | 5.6 | 1.7 | — | 1.9 | 5.6 | 1.7 | — |
| | Component (D) | HAT | 0.4 | 0.4 | 0.4 | 0.4 | 0.4 | 0.4 | 0.4 | 0.4 | 0.4 |
| | Component (E) | PM-21 | 0.25 | 0.25 | 0.25 | 0.25 | 0.25 | 0.25 | 0.25 | 0.25 | 0.25 |
| | Others | Antage | 0.1 | 0.1 | 0.1 | 0.1 | 0.1 | 0.1 | 0.1 | 0.1 | 0.1 |
| | | W-500 | | | | | | | | | |
| | | SH-30 | 0.07 | 0.07 | 0.07 | 0.07 | 0.07 | 0.07 | 0.07 | 0.07 | 0.07 |
| | | Methyl ethyl | 50 | 50 | 50 | 50 | 50 | 50 | 50 | 50 | 50 |
| | | ketone | | | | | | | | | |
| High | Component (B) | FA321M | — | — | — | — | — | 3.7 | 3.7 | 3.7 | 3.7 |
| refractive | Component (E) | PM-21 | — | — | — | — | — | 0.4 | 0.4 | 0.4 | 0.4 |
| index | Component (F) | UR658 | 50 | 50 | 50 | 50 | 50 | 11.0 | 11.0 | 11.0 | 11.0 |
| layer | | OZ-S30K | — | — | — | — | — | 82.7 | 82.7 | 82.7 | 82.7 |
| | | EAF5503 | 50 | 50 | 50 | 50 | 50 | — | — | — | — |
| | Others | L-7001 | 1 | 1 | 1 | 1 | 1 | 2.1 | 2.3 | 2.2 | 2.3 |

| Refractive index of high refractive | | 1.62 | 1.62 | 1.62 | 1.62 | 1.62 | 1.65 | 1.65 | 1.65 | 1.65 |
|---|---|---|---|---|---|---|---|---|---|---|
| indexlayer@λ633 nm | | | | | | | | | | |
| Film thickness of high refractive | | 220 | 220 | 220 | 220 | 220 | 100 | 100 | 100 | 100 |
| indexlayer (nm) | | | | | | | | | | |
| Film thickness of photosensitive resin | | 8 | 8 | 8 | 8 | 8 | 8 | 8 | 8 | 8 |
| layer (μm) | | | | | | | | | | |
| Transmittance | b* | 4.69 | 7.41 | 9.21 | 4.69 | 3.35 | 4.43 | 8.60 | 3.12 | 2.23 |
| Reflectance | Y | 8.30 | 8.42 | 8.47 | 8.30 | 8.62 | 8.42 | 8.47 | 8.58 | 8.92 |
| | b* | 0.21 | 1.72 | 2.32 | 0.21 | −0.97 | 0.00 | 2.14 | −0.87 | −0.62 |

| | | | | | | | | | |
|---|---|---|---|---|---|---|---|---|---|
| Salt water spray test | A | A | A | A | C | A | A | A | C |
| Transmittance (%) | 89.26 | 88.79 | 88.36 | 89.26 | 89.48 | 88.97 | 89.99 | 89.62 | 90.25 |
| Haze | 0.47 | 0.44 | 0.43 | 0.47 | 0.27 | 0.45 | 0.47 | 0.46 | 0.30 |
| Development residue test | A | A | A | A | A | A | A | A | A |
| Standardization of reflectance R | 87.09% | 88.35% | 88.87% | 87.09% | 90.50% | 88.40% | 88.92% | 90.08% | 93.61% |

TABLE 5

| | | | Comp. | Comp. | Comp. | Comp. | Comp. | Comp. |
|---|---|---|---|---|---|---|---|---|
| | | | Ex. 10 | Ex. 11 | Ex. 12 | Ex. 13 | Ex. 14 | Ex. 15 |
| Photo- | Component (A) | A1 | 60 | 60 | 60 | 60 | 60 | 60 |
| sensitive | Component (B) | T-1420(T) | 40 | 40 | 40 | 40 | 40 | 40 |
| resin | Component (C) | IRGACURE | — | — | — | — | — | 1.7 |
| layer | | OXE 01 | | | | | | |
| | | IRGACURE | 1.9 | 3.7 | 5.6 | 1.7 | 1.7 | — |
| | | 379 | | | | | | |
| | | DETX | 1.9 | 3.7 | 5.6 | 1.7 | — | — |
| | Component (D) | HAT | 0.4 | 0.4 | 0.4 | 0.4 | 0.4 | 0.4 |
| | Component (E) | PM-21 | 0.25 | 0.25 | 0.25 | 0.25 | 0.25 | 0.25 |
| | Others | Antage | 0.1 | 0.1 | 0.1 | 0.1 | 0.1 | 0.1 |
| | | W-500 | | | | | | |
| | | SH-30 | 0.07 | 0.07 | 0.07 | 0.07 | 0.07 | 0.07 |
| | | Methyl ethyl | 50 | 50 | 50 | 50 | 50 | 50 |
| | | ketone | | | | | | |
| High | Component (A) | A1 | — | — | — | — | — | — |
| refractive | | A3 | 7 | 8 | 9 | 10 | 11 | — |
| index | Component (B) | T-1420(T) | — | — | — | — | — | — |
| layer | | FA321M | 7 | 8 | 9 | 10 | 11 | — |
| | Component (C) | IRGACURE | — | — | — | — | — | — |
| | | OXE 01 | | | | | | |
| | | HAT | 0.3 | 1.3 | 2.3 | 3.3 | 4.3 | — |
| | | 3MT | — | — | — | — | — | — |
| | Component (E) | PM-21 | 0.3 | 1.3 | 2.3 | 3.3 | 4.3 | — |
| | | Phosmer-M | — | — | — | — | — | — |
| | Component (F) | OZ-S40K-AC | — | — | — | — | — | — |
| | | OZ-S30K | 84 | 85 | 86 | 87 | 88 | — |
| | | EA0200 | — | — | — | — | — | — |
| | | EA-HC931 | — | — | — | — | — | — |
| | Others | Antage | — | — | — | — | — | — |
| | | W-500 | | | | | | |
| | | L-7001 | 1.7 | 2.7 | 3.7 | 4.7 | 5.7 | — |

| Refractive index of high refractive | | 1.63 | 1.64 | 1.64 | 1.65 | 1.65 | 1.47 |
|---|---|---|---|---|---|---|---|
| index layer@λ633 nm | | | | | | | |
| Film thickness of high refractive | | 100 | 100 | 100 | 100 | 100 | 0 |
| index layer (nm) | | | | | | | |
| Film thickness of photosensitive resin | | 8 | 8 | 8 | 8 | 8 | 8 |
| layer (μm) | | | | | | | |
| Transnittance | b* | 4.56 | 7.11 | 8.90 | 3.91 | 2.79 | 1.42 |
| Reflectance | Y | 8.36 | 8.40 | 8.47 | 8.44 | 8.77 | 9.53 |
| | b* | 0.10 | 1.51 | 2.23 | −0.33 | −0.80 | −1.48 |

| | | | | | | |
|---|---|---|---|---|---|---|
| Salt water spray test | A | A | A | A | C | A |
| Transnittance (%) | 89.12 | 89.41 | 89.17 | 89.44 | 89.86 | 89.85 |
| Haze | 0.46 | 0.44 | 0.45 | 0.47 | 0.29 | 1.03 |
| Development residue test | A | A | A | A | A | A |
| Standardization of reflectance R | 87.74% | 88.22% | 88.90% | 88.58% | 92.05% | 100.00% |

| | | | Comp. | Comp. | Comp. | Comp. | |
|---|---|---|---|---|---|---|---|
| | | | Ex. 16 | Ex. 17 | Ex. 18 | Ex. 19 | Reference |
| Photo- | Component (A) | A1 | — | — | — | — | Single |
| sensitive | Component (B) | T-1420(T) | — | — | — | — | body of |
| resin | Component (C) | IRGACURE | — | — | — | — | substrate |
| layer | | OXE 01 | | | | | |
| | | IRGACURE | — | — | — | — | |
| | | 379 | | | | | |
| | | DETX | — | — | — | — | |
| | Component (D) | HAT | — | — | — | — | |
| | Component (E) | PM-21 | — | — | — | — | |
| | Others | Antage | — | — | — | — | |
| | | W-500 | | | | | |
| | | SH-30 | — | — | — | — | |
| | | Methyl ethyl | — | — | — | — | |
| | | ketone | | | | | |
| High | Component (A) | A1 | 30 | 10 | 60 | 60 | |
| refractive | | A3 | — | — | — | — | |
| index | Component (B) | T-1420(T) | — | — | 40 | 40 | |
| layer | | FA321M | — | — | — | — | |
| | Component (C) | IRGACURE | 1.7 | 1.7 | 1.7 | 1.7 | |
| | | OXE 01 | | | | | |
| | | HAT | — | 0.4 | 0.4 | 0.4 | |
| | | 3MT | 1.0 | — | — | — | |
| | Component (E) | PM-21 | 0.25 | — | 0.25 | 0.25 | |
| | | Phosmer-M | — | 2.0 | — | — | |
| | Component (F) | OZ-S40K-AC | 102.5 | 193.64 | — | — | |
| | | OZ-S30K | — | — | 102.5 | 190.4 | |
| | | EA0200 | 50 | 50 | — | — | |
| | | EA-HC931 | 20 | 40 | — | — | |
| | Others | Antage | 0.1 | 0.1 | 0.1 | 0.1 | |
| | | W-500 | | | | | |
| | | L-7001 | 0.07 | 0.07 | 0.07 | 0.07 | |

| Refractive index of high refractive | | 1.62 | 1.65 | 1.56 | 1.58 | — |
|---|---|---|---|---|---|---|
| index layer@λ633 nm | | | | | | |
| Film thickness of high refractive | | 8000 | 8000 | 8000 | 8000 | — |
| index layer (nm) | | | | | | |
| Film thickness of photosensitive resin | | 0 | 0 | 0 | 0 | — |
| layer (μm) | | | | | | |
| Transnittance | b* | 1.56 | 1.48 | 1.37 | 2.04 | 0.93 |
| Reflectance | Y | 9.16 | 9.03 | 9.28 | 8.94 | 16.81 |
| | b* | −1.45 | −1.34 | −1.58 | −1.39 | −1.53 |

| | | | | | |
|---|---|---|---|---|---|
| Salt water spray test | C | C | C | C | D |
| Transnittance (%) | 90.21 | 90.52 | 89.93 | 90.25 | 82.60 |
| Haze | 1.17 | 1.16 | 1.10 | 1.32 | 1.56 |
| Development residue test | C | C | C | C | — |
| Standardization of reflectance R | 96.15% | 94.79% | 97.41% | 93.88% | 176.48% |

The compositions of the components shown in Tables 2 to 5 are parts by mass.

As shown in Tables 2 to 5, in the Examples, the standardization value of R (reflectance) became 90% or less, i.e. the reflectance was sufficiently reduced. Further, resistance to salt water spray test was sufficient. Further, developability was excellent with no development residues being formed. It was confirmed that the light transmittance of the photosensitive resin layer and the high-refractive index layer was high. Comparative Example 15 shows a result where only the photosensitive resin layer was provided.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification are incorporated herein by reference in its entirety.

### DESCRIPTION OF NUMERICAL SYMBOLS

1. Transfer-type photosensitive refractive index adjustment film
10. Supporting film
20. Photosensitive resin layer
30. High-refractive index layer
40. Protective film
50. Substrate with transparent electrode pattern
50a. Transparent electrode pattern
100. Laminate
101. Transparent substrate
102. Touch screen
103. Transparent electrode (X-position coordinate)
104. Transparent electrode (Y-position coordinate)
105. Lead-out wiring
106. Connection electrode
107. Connection terminal
123. Refractive index adjustment pattern

1. A transfer-type photosensitive refractive index adjustment film comprising:
a support film, a photosensitive resin layer provided on the support film and a high-refractive index layer provided on the photosensitive resin layer,
the photosensitive resin layer comprises a photopolymerizable compound and a photopolymerization initiator, and
the photopolymerization initiator comprises an oxime ester compound or a phosphine oxide compound.

2. The transfer-type photosensitive refractive index adjustment film according to claim 1, wherein the minimum value of the visible ray transmittance at a wavelength of 400 to 700 nm of the photosensitive resin layer and the high-refractive index layer is 90.00% or more.

3. The transfer-type photosensitive refractive index adjustment film according to claim 1, wherein the high-refractive index layer comprises a compound having a triazine ring or a compound having an isocyanuric acid.

4. The transfer-type photosensitive refractive index adjustment film according to claim 1, wherein the high-refractive index layer comprises a compound having a fluorene skeleton.

5. The transfer-type photosensitive refractive index adjustment film according to claim 1, wherein the high-refractive index layer comprises a metal oxide.

6. The transfer-type photosensitive refractive index adjustment film according to claim 5, wherein the metal oxide is at least one selected from the group consisting of zirconium oxide, titanium oxide, tin oxide, zinc oxide, indium tin oxide, indium oxide, aluminum oxide, silicon oxide and yttrium oxide.

7. The transfer-type photosensitive refractive index adjustment film according to claim 1, wherein the refractive index at a wavelength of 633 nm of the high-refractive index layer is 1.50 to 1.90.

8. The transfer-type photosensitive refractive index adjustment film according to claim 1, wherein the thickness of the high-refractive index layer is 10 to 500 nm.

9. The transfer-type photosensitive refractive index adjustment film according to claim 1, wherein the photosensitive resin layer comprises a binder polymer.

10. The transfer-type photosensitive refractive index adjustment film according to claim 9, wherein the binder polymer has a carboxyl group.

11. The transfer-type photosensitive refractive index adjustment film according to claim 9, wherein the binder polymer comprises a structural unit derived from at least one compound selected from the group consisting of (meth)acrylic acid, (meth)acrylic acid glycidyl ester, (meth)acrylic acid benzyl ester, styrene, (meth)acrylic acid methyl ester, (meth)acrylic acid ethyl ester, meth(acrylic) butyl ester and (meth)acrylic acid 2-ethylhexyl ester.

12. The transfer-type photosensitive refractive index adjustment film according to claim 8, wherein the photosensitive resin layer comprises a phosphoric acid ester compound.

13. The transfer-type photosensitive refractive index adjustment film according to claim 1, wherein the total thickness of the photosensitive resin layer and the high-refractive index layer is 30 μm or less.

14. A method for forming a refractive index adjustment pattern that comprises:
a step of laminating the high-refractive index layer and the photosensitive resin layer by using the transfer-type photosensitive refractive index adjustment film according to claim 1 such that the high-refractive index layer is in close contact with a substrate; and
a step of forming a refractive index adjustment pattern in which, after exposing prescribed parts of the high-refractive index layer and the photosensitive resin layer on the substrate, parts other than said prescribed parts are removed, thereby to form a refractive index adjustment pattern.

15. An electronic component having a refractive index adjustment pattern obtained by the forming method according to claim 14.
